(19) United States
(12) Patent Application Publication
(10) Pub. No.: US 2017/0365569 A1
(43) Pub. Date: Dec. 21, 2017

(54) Contact Bumps and Methods of Making Contact Bumps on Flexible Electronic Devices

(71) Applicant: SMARTRAC TECHNOLOGY GmbH, Dresden (DE)

(72) Inventor: Frank Kriebel, Lichtenberg (DE)

(21) Appl. No.: 15/635,189

(22) Filed: Jun. 27, 2017

Related U.S. Application Data
(63) Continuation-in-part of application No. 14/952,958, filed on Nov. 26, 2015.
Application No. 14/952,958 is a continuation-in-part of application No. 14/094,714, filed on Dec. 2, 2013, now Pat. No. 9,215,809.

(51) Int. Cl. H01L 23/00; H01L 23/538; H01L 23/498; H01L 21/48

(52) U.S. Cl. CPC H01L 24/11; H01L 24/81; H01L 24/75; H01L 24/742; H01L 24/15; H01L 21/4825; H01L 23/5387; H01L 23/4985; H01L 21/4853; H01L 24/05

(57) ABSTRACT

Contact bumps between a contact pad and a substrate can include a rough surface that can mate with the material of the substrate of which may be flexible. The rough surface can enhance the bonding strength of the contacts, for example, against shear and tension forces, especially for flexible systems such as smart label and may be formed via roller or other methods.

The present application is a continuation-in-part of U.S. application Ser. No. 14/952,958, filed on Nov. 26, 2015, entitled “Contact bumps methods of making contact bumps”; which is a continuation-in-part of U.S. Ser. No. 14/094,714, filed on Dec. 2, 2013, entitled “Contact bumps methods of making contact bumps”, now U.S. Pat. No. 9,215,809 entitled “Contact bumps methods of making contact bumps”; which is a continuation-in-part of PCT patent application PCT/DE2013/000451, filed on Aug. 9, 2013, entitled “Contact bump connection and contact bump and method for producing a contact bump connection”; which claims priority of German patent application 10 2012 015 811.4, filed on Aug. 10, 2012, entitled “Contact bump connection and contact bump and method for producing a contact bump connection”, all of which are hereby incorporated by reference.

### FIELD OF TECHNOLOGY

This disclosure relates generally to semiconductor manufacturing. Example embodiments may relate to methods, apparatus, and systems wherein contact bumps formed on flexible supporting structures include a rough surface that can mate with the surface of a contact pad material which in one or more embodiments may be flexible. The rough surface can enhance the bonding strength between the contact bumps and the contact pad, for example, against shear and tension forces, especially for flexible electronic devices. In one embodiment, the contact and mating may be formed via roller or other methods.

### BACKGROUND

Contact bumps play an essential role in the field of semiconductor technology for contacting semiconductor devices or chips with other substrates or carriers such as printed circuit boards.

Different techniques for forming contact bumps can be used for the connection of pads of semiconductor devices, chips, or substrates. An example is the so-called flip-chip technique, in which the bumps are arranged as connection elements on the chip and are optionally contacted with an additional pressure sensitive adhesive to the connecting pads of a carrier substrate. The quality of the connection established between connection surfaces of the carrier substrate and the bumps plays an essential role in the later use of the components.

In the mechanical method, a gold wire can be used, which is shaped at its tip by the action of heat into a ball. The spherical tip of the gold wire is pressed with a suitable tool to a connection surface of the substrate, so that the ball is deformed by the force applied. Then the wire is pinched off, torn or sheared across the globe, so that a bulbous body with a wire remaining on top as bumps or contact bump remains on the substrate. The remaining on the tip of bulbous body is then flattened generally in the same or another tool. This technique is known as mechanical stud bumping and is known for example from U.S. Pat. No. 5,060,843. The connection of the material of the gold bump with metallization of the pad is performed via the pressure applied and the resulting micro-welding between the two boundary surfaces.

A general limitation of all know connecting technologies is the limited applicability to flexible electronic components like flexible semiconductors.

### SUMMARY

In some embodiments, the present invention discloses contact bumps and methods of making contact bumps on flexible conductive materials that are configured to form contact with corresponding contact pads. The contact bumps and the corresponding contact pads can be pressed together with a bonding force, which can drive the contact bumps into the material of the contact pads.

The contact bumps on flexible conductive materials can include a rough surface that can mate with the material of the contact pads. The material of the contact bump can be harder than the material of the contact pads, thus when pressed, the contact pads can be deformed to flow around the contact bump, forming an improved contact connection. The improved contact connection can include enhanced bonding strength of the contacts, for example, against shear and tension forces, especially for flexible systems such as smart cards.

The present invention may then be applied towards completely flexible or semi-flexible systems wherein the flexible conductive and facultatively present intervening layers constitute part of electronic devices originating from conventional or printed Thin Film Technology

In some embodiments, an oscillatory force can be used to press the contact bumps into the contact pads. The oscillatory force can include a substantially constant component, such as a pressing force, and an oscillatory component, such as an ultrasonic vibration, to allow for a flowing of the material of the contact pads around the contact bump.

In some embodiments processing and manufacturing may also provide for roller elements wherein then a force, such as applied by a roller, may be used such as for instance wherein the roller or rollers assert pressure on a pair of two contact partners to form a galvanic contact such as broadly continuous rolling pressing together may form a flexible device.

### BRIEF DESCRIPTIONS OF THE DRAWINGS

FIGS. 1A-1D illustrate various prior art contact bumps, which rely on the bonding strength of the contact bump with the contact pad, together with the increase in contact areas.

FIGS. 2A-2B illustrate a contact bump and a corresponding contact bonding process according to some embodiments.

FIGS. 3A-3F illustrate different configurations for the contact bump according to some embodiments.

FIGS. 4A-4F illustrate various configurations for the cross section of the contact bump according to some embodiments.

FIGS. 5A-5E illustrate other configurations for the contact bump according to some embodiments.

FIGS. 6A-6F illustrate other configurations for the contact bump according to some embodiments.

FIGS. 7A-7B illustrate a contact bump configuration according to some embodiments.

FIGS. 8A-8B illustrate flow charts for forming contact bumps according to some embodiments.

FIG. 9 illustrates a bonded configuration of a contact bump with a contact pad according to some embodiments.

FIGS. 10-11A and 11B illustrate a process flow for forming the bonded configuration between a contact bump and a contact pad according to some embodiments.

FIGS. 12A-12B illustrate another process flow for forming the bonded configuration between a top contact bump and a bottom contact bump according to some embodiments.

FIGS. 13A-13B illustrate flow charts for forming contact with contact bumps according to some embodiments.

FIGS. 14A-14B illustrate a RFID card having a contact bump bonding according to some embodiments.

FIG. 15 illustrates a flow chart for forming flexible element such as a substrate, antenna or device contact with contact bumps according to some embodiments.

FIGS. 16A-16D illustrate contact bump configurations for a rectangular contact pad according to some embodiments.

FIGS. 17A-17C illustrate other configurations for the contact bump according to some embodiments.

FIGS. 18A-18B illustrate flow charts for forming contact connection for a device according to some embodiments.

FIGS. 19A-19B illustrate a contact connection with a contact bump according to some embodiments.

FIGS. 20A-20B illustrate a bonding process between two contact pads according to some embodiments.

FIGS. 21A-21C illustrate bonding configurations according to some embodiments.

FIGS. 22A-22B illustrate flow charts for forming a contact connection according to some embodiments.

FIGS. 23A-23C illustrate contact bump configurations on a flexible substrate.

FIGS. 24A-24C illustrate flow charts for forming a bump for flexible substrates according to some embodiments.

FIGS. 25A-25D illustrate contact bump configurations on a flexible substrate in different configurations and cross sections.

FIGS. 26A-26B illustrate flow charts for forming a bump for flexible substrates according to some embodiments.

FIGS. 27A-27C illustrate forming contact bump configurations on a flexible substrate with rollers.

FIGS. 28A-28C illustrate forming contact bump configurations on a flexible substrate with rollers.

FIGS. 29A-29B illustrate forming contact bump configurations on a flexible substrate with rollers.

FIGS. 30A-30B illustrate flow charts for forming bumps and devices for flexible substrates and devices according to some embodiments.

FIG. 31 illustrate flow charts for forming bumps and devices for flexible substrates and devices according to some embodiments.

### DETAILED DESCRIPTION OF THE DRAWINGS

In some embodiments, the present invention discloses methods and systems for bonding terminal pads of a chip (flexible chip, not crystal) with corresponding contact pads of a substrate, which can be another (device) or a system board. The bonding process can include forming a contact bump on a terminal pad, before bonding the contact bump with a corresponding contact pad.

In some embodiments, the contact bump can include an irregular surface, for example, a surface having recesses and protrusions, which can include micro roughness textures of the surface, that are caused by the formation process of the contact bump. The micro roughness textures can include roughness in an order of micrometers, such as less than 30, less than 10, less than 5, less than 1, or less than 0.1 microns. The roughness can be characterized by maximum peak-to-valley height, by the average peak-to-valley height, or by the mean roughness index.

In some embodiments, the contact bump can have a hardness higher than the hardness of the corresponding contact pad. Thus, in some cases, during the bonding of the contact bump with the corresponding contact pad, the material of the corresponding contact pad can be deformed, with minimum effect on the contact bump.

Further, the structure of the contact bump, e.g., the shapes and sizes of the contact bump, can be such that the material of the corresponding contact pad can be driven away from the contact bump to facilitate a strong surface interaction between the contact bump and the corresponding contact pad.

During the bonding of the contact bump with the contact pad, for example, by applying a contact force on the contact bump to drive the contact bump into the contact pad material, the contact pad material can be driven to form intimate mating with the irregular surface, for example, by filling the recesses or flowing around the protrusion. The intimate contact between the contact pads and the irregular surface of the contact bump can significantly improve the bonding strength of the contact bonding, especially enhancing shear and tension bonding characteristics which can be required in flexible substrates such as smart cards.

An oscillatory force, such as at an ultrasonic frequency, can be used during the driving of the contact bump to the corresponding contact pad. For example, due to the rough surface of the contact bump, an intermesh effect can be created. And due to the oscillation, a heat can be created for a short time, such as a few milliseconds, which can create an intermetallic connection between the two materials.

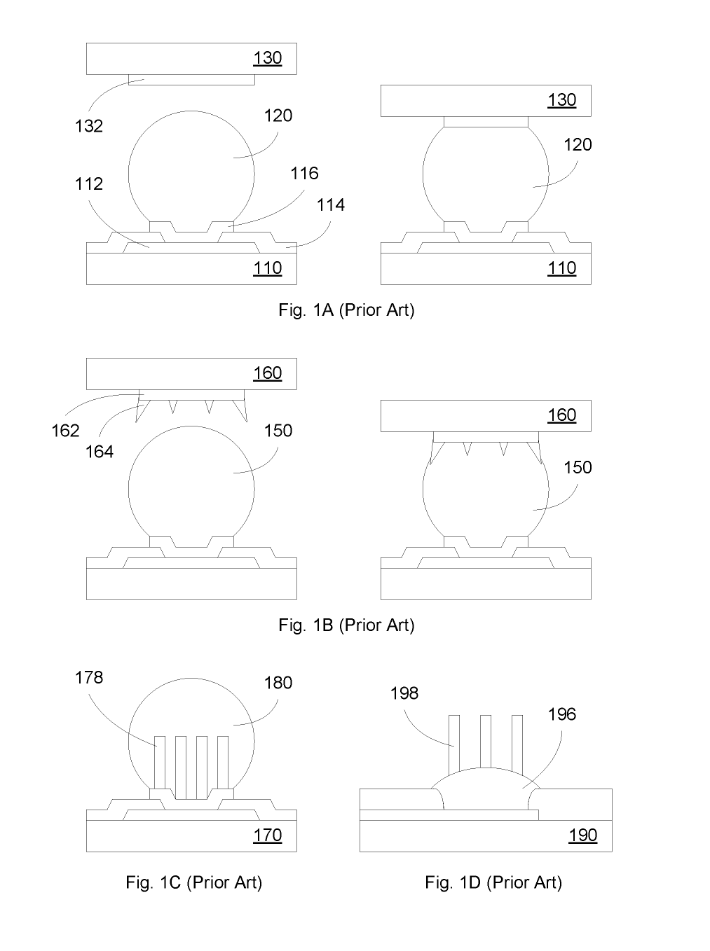

FIGS. 1A-1D illustrate various prior art contact bumps, which rely on the bonding strength of the contact bump with the contact pad, together with the increase in contact areas. The contact pads or the contact bump can have pins, which can increase the contact area for improving the bonding strength.

In FIG. 1A, a chip 110 can have a terminal pad 112 disposed on an external surface of the chip. Passivation layer 114 can be included, for example, to isolate the terminal pad 112 from neighbor terminal pads. A layer 116 containing an under-bump material (UBM), such as an alloy of aluminum, nickel and copper, can be formed to facilitate the bonding of the contact bump 120 to the terminal pad 112. The contact bump 120 can include solder material or palladium material. A substrate 130 having contact pad 132 can be brought to the contact bump 120 for bonding between the contact bump 120 and the contact pad 132.

In FIG. 1B, pins 164 can be formed on the contact pad 162 of the substrate 160. The contact between the contact pad 162 and the contact bump 150 can be enhanced by the penetration of pins 164 into the contact bump 150. In FIG. 1C, contact bump 180 can be enforced by pins 178, which can enhance the bonding of the contact bump 180 with the chip 170. In FIG. 1D, pins 198 can protrude from the contact bump 196, which can enhance the bonding of the contact bump 196, bonding the chip 190 with a contact pad of the substrate.

In some embodiments, the present invention discloses contact bonding processes, and the contact bumps fabricated for the contact bonding processes, that can further include a physical attachment between the contact bump and the contact pad, in addition to the surface chemical bonding. The physical attachment can include multiple protrusions between the contact bump and the contact pad, thus can provide separation resistance. For example, the contact bump can have an irregular surface that includes recesses and protrusions. The irregular surface of the contact bump can be mated to a corresponding surface of the contact pad. The recesses and protrusions at the interface of the bonded surfaces can provide an additional resistance to any separation force in the shear direction.

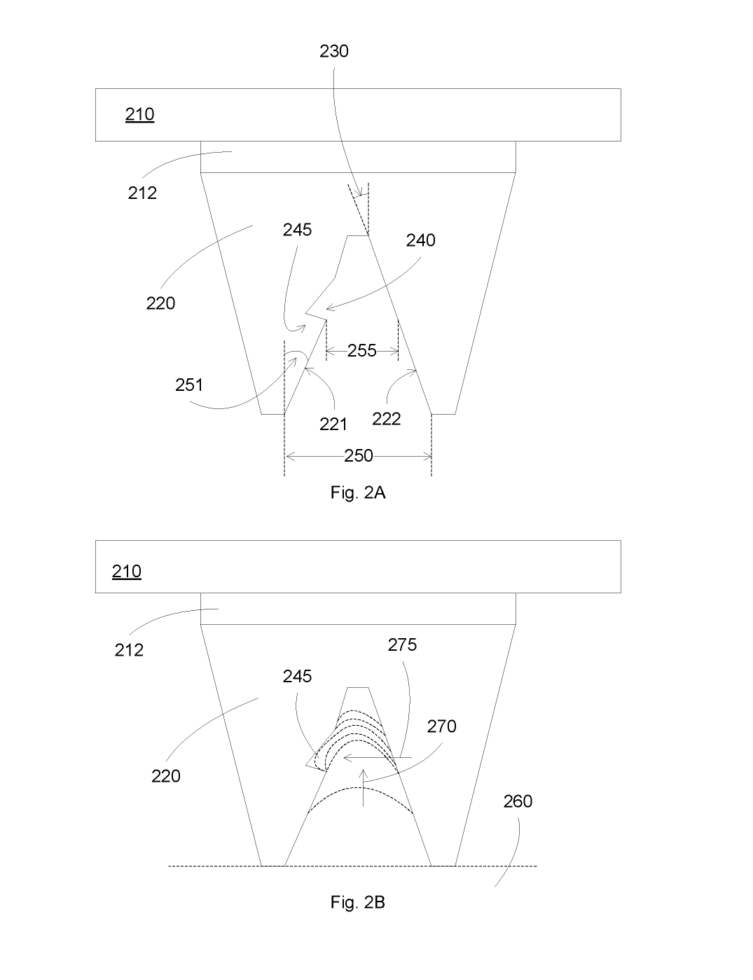

FIGS. 2A-2B illustrate a contact bump and a corresponding contact bonding process according to some embodiments. A contact bump 220 can be fabricated on a terminal pad 212 of a substrate 210, such as a semiconductor chip, and of note which may be a flexible chip. The contact bump 220 is shown to be directly formed on the terminal pad 212, but other configurations can also be used, such as a passivation layer for isolating the contact bump 220 with neighbor contact bumps, or an UBM layer for improving adhesion and contact resistance between the contact bump 220 and the terminal pad 212.

The contact bump 220 can have two facing surfaces 221 and 222, e.g., inner surfaces of the contact bump. A surface, such as surface 221, can have irregularities, e.g., a non-smooth surface with recess 240 and/or protrusion 245, which can provide physical bonding to a bonded contact pad against tensile separation. The irregularities can include recesses and protrusions having dimensions of a few percent of the contact bump dimension, such as greater than about 0.1 micron, greater than 1, 3 or 5 microns, or greater than about 10 microns. The irregularities can include recesses and protrusions having dimensions less than 100 microns, less than 50, 20, 10, 5, 3 microns, or less than about 1 microns. The irregularity can include surface roughness, with peak to valley height in order of a few nanometers to multiple micrometers, such as between about 10 nm and about 100 microns.

The two surfaces can be tapered upward, e.g., forming a taper angle 251 with the direction perpendicular to the terminal pad 212, with the lower opening 250 can be larger than the upper opening 255. The taper of the surfaces can force the material from the contact pad to rise upward, which can be driven sideway to fill the recess 240 to flow around the protrusion 245. The taper angle can be greater than zero degree, such as greater than about 10 degrees, or can be greater than about 30 degrees. Other surface configurations can be used, such as curve surfaces.

The facing surface, e.g., surface 222, can form an angle 230 with the direction of the bonding force. Typically, the contact bump can be pressed against a contact pad 260 in a direction perpendicular to the terminal pad 212. Thus, the surface 222 can form an angle 230 with the normal direction of the terminal pas 212. When a force is applied to the contact bump for bonding with the contact pad, materials from the contact pad can rise 270 to make contact with the surface 222. Since the surface 222 forms an angle with the applied force, the normal force at the surface 222 can have a side component 275, which can direct the material sideway to fill in the recess 245 or to flow around the protrusion. The angle can be greater than zero degree, such as greater than about 10 degrees, or can be greater than about 30 degrees.

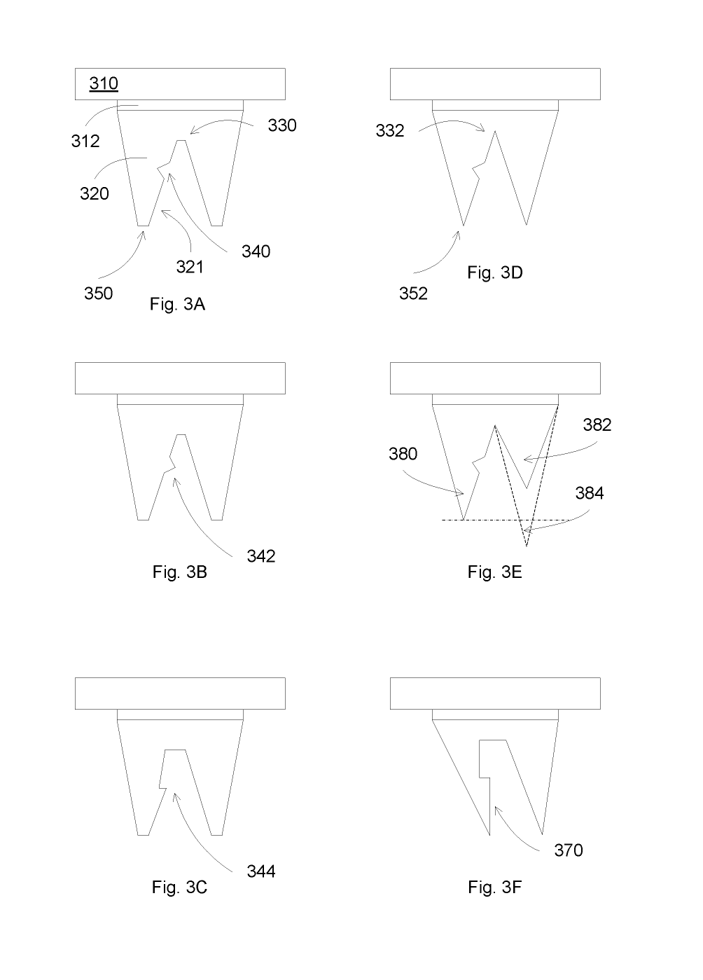

FIGS. 3A-3F illustrate different configurations for the contact bump according to some embodiments. A contact bump 320 can be bonded to a terminal pad 312 on a substrate 310. In FIG. 3A, a contact bump can have a recess 340 on an inner surface 321, which forms angle of about 15 degrees with the normal direction of terminal pad 312. The tips 350 of the contact bump can be flat. The top portion 330 of the inner surface 321 can also be flat when facing with the opposite surface. In FIG. 3B, the contact bump can have a protrusion 342 on an inner surface. In FIG. 3C, the contact bump can have a combination of protrusion and recess 344 on an inner surface. Other irregular surfaces can be used, for example, multiple recesses and protrusions on an inner surface of the contact bump. Also, the recesses and protrusions of the irregular surface can be random, generated from a deposition process when forming the contact bump.

In FIG. 3D, the tips 352 of the contact bump can be sharp, which can facilitate the penetration of the contact bump to the contact pad. The top portion 332 of the inner surface can also be sharp. In FIG. 3E, the tips of the contact bump can have different height. For example, one tip 382 can be shorter than the other tip 380. The tip 384 can be longer than the other tip 380. In FIG. 3F, the surface 370 having the irregularities can be in the normal direction of the terminal pad 312. The opposite facing surface can form an angle with the normal direction, which can provide a horizontal or side force to drive the excess material to fill in the gaps in the irregular surface 370.

The connection area can be covered the entire surface on the substrate through the layer deposition. The generation of the bump can be in several stages. Adhesion and barrier layer can be deposited by sputtering or evaporation on the connecting metallization and then possibly reinforced by electroplating. For example, Cr, stainless steel, Cu, Ti, Pt, Au, TiW, TiW, Ni, or any alloys or combinations can be used. The contact material can include Au, Cu, Ni, SnPb, AuSn, SnAg, In, or any alloys or combinations, which can be applied by vapor deposition or electrodeposition. For solder bump, SnPb, SnAg and In can be used. For welding, Au and In can be used. Bumps of Au, Ni and Cu may be used by an additional application of adhesive or solder bumps on the substrate or on the side of a solder or adhesive bond.

Alternatively, Al or Cu alloy can be used with silicon wafers (flexible electronic devices, build with thin film layers—with vacuum deposition processes or printed layers), which can be deposited without the use of masks, e.g., by an electroless plating, using Ni or Pd on the contact metallization. With Cu and Au, this can normally be strengthened.

In some embodiments, the present invention can provide methods to produce contact bumps and bumps which allow the production of an electrical connection of the bump with bond pads, or other connection elements to form a more effective and a higher connection reliability.

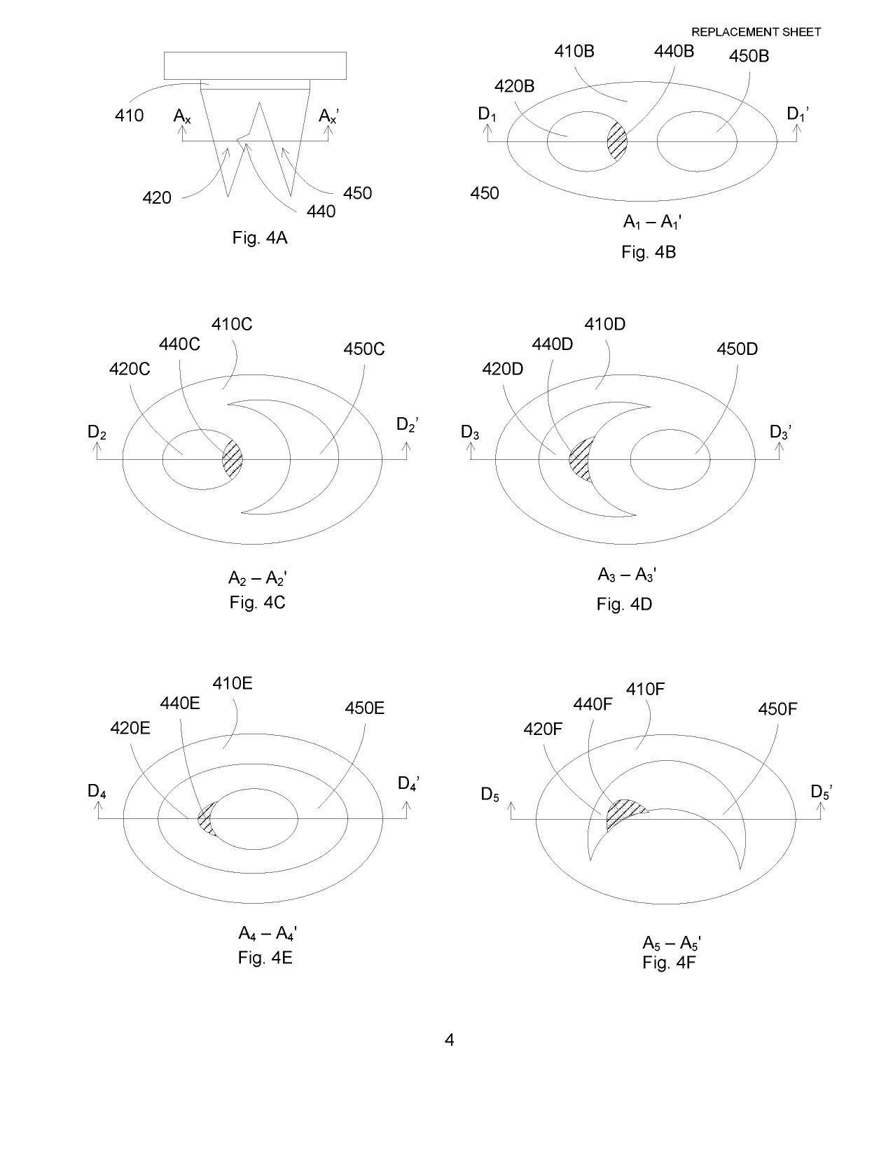

FIGS. 4A-4E illustrate various configurations for the cross section of the contact bump according to some embodiments. In FIG. 4A, a cross section view of the contact bump can show two contact tips 420 and 450 bonded to a terminal pad 410. Recess 440 can be provided at the contact tip 420. One recess 440 is shown, but the contact bump can have other irregularities, such as multiple recesses or protrusions, in a surface of one contact tip 420 or 450 or in surfaces of both contact tips 420 and 450. Cut line AₓAₓ′ can show different cross section views of the contact bump.

FIG. 4B shows a cross section A₁A₁′ (among the different cross sections AₓAₓ′ of FIG. 4A) of a contact bump as shown in FIG. 4A, whose cross section can be the cross section C₁C₁′. The contact bump can include two pyramid-like cones 420B (which can correspond to contact tip 420) and 450B (which can correspond to contact tip 450) protruded from the terminal pad 410B (which can correspond to terminal pad 410). Recess 440B (which can correspond to recess 440) can be shown on a surface of cone 420B.

FIG. 4C shows a cross section A₂A₂′ (among the different cross sections AₓAₓ′ of FIG. 4A) of a contact bump as shown in FIG. 4A, whose cross section can be the cross section C₂C₂′. The contact bump can include a pyramid-like cone 420C (which can correspond to contact tip 420), together with a half-moon cone 450C (which can correspond to contact tip 450) protruded from the terminal pad 410C (which can correspond to terminal pad 410). Recess 440C (which can correspond to recess 440) can be shown on a surface of cone 420C. The recess 440C can be surrounded by a half moon surface of cone 450C, which can provide horizontal force to the recess at multiple direction, allowing the material from the contact pad to easily fill in the recess.

FIG. 4D shows a cross section A₃A₃′ (among the different cross sections AₓAₓ′ of FIG. 4A) of a contact bump as shown in FIG. 4A, whose cross section can be the cross section C₃C₃′. The contact bump can include a half moon cone 420D (which can correspond to contact tip 420), together a pyramid-like cone 450D (which can correspond to contact tip 450) protruded from the terminal pad 410D (which can correspond to terminal pad 410). Recess 440D (which can correspond to recess 440) can be shown on a surface of cone 420D.

FIG. 4E shows a cross section A₄A₄′ (among the different cross sections AₓAₓ′ of FIG. 4A) of a contact bump as shown in FIG. 4A, whose cross section can be the cross section C₄C₄′. The contact bump can include a circular cone 420E/450E (which can correspond to contact tips 420/450) protruded from the terminal pad 410E (which can correspond to terminal pad 410). The circular cone can have the shape of an inverted volcano having a hollow portion in the middle. Recess 440E (which can correspond to recess 440) can be shown on a surface of the circular cone.

FIG. 4F shows a cross section A₅A₅′ (among the different cross sections AₓAₓ′ of FIG. 4A) of a contact bump as shown in FIG. 4A, whose cross section can be the cross section C₅C₅′. The contact bump can have a shape of a partially surrounding wall, such as a half-moon shape, protruded from the terminal pad 410F (which can correspond to terminal pad 410), with facing surfaces or facing extended portions 420F (which can correspond to contact tip 420) and 450F (which can correspond to contact tip 450). Recess 440F (which can correspond to recess 440) can be shown on a surface of the extended portion 420F.

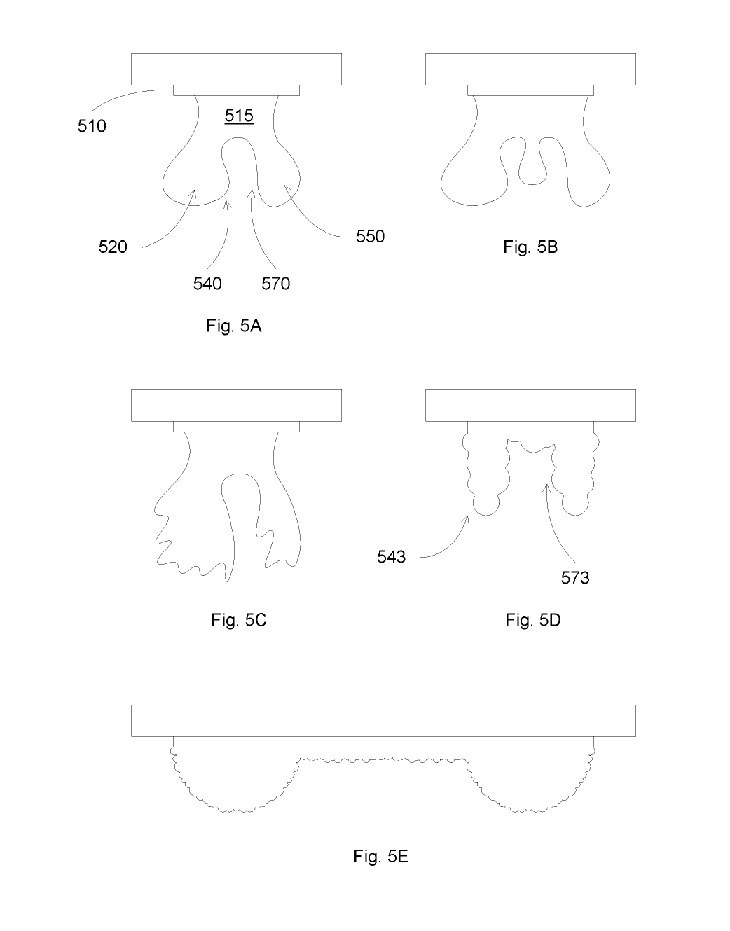

FIGS. 5A-5E illustrate other configurations for the contact bump according to some embodiments. In FIG. 5A, a cross section of a contact bump 515 is shown, which is disposed on a terminal pad 510. The contact bump 515 shows two tips 520 and 550, having a mushroom shape. The mushroom shape can include a recess or a protrusion at the end of the tip, or a larger tip portion than a body portion. The mushroom shape 520 can include a protrusion 540. The mushroom shape 550 can include an angle surface 570. In FIG. 5B, the contact bump can include three mushroom tips. In FIG. 5C, the contact bump can include mushroom tips having irregular patterns. FIG. 5D shows a contact bump having contact tips 643 with rough surfaces 673. FIG. 5E shows a contact bump having different contact tips with different rough surfaces. Other shapes can be formed, such as more than three tips, different mushroom shapes, or a combination of mushroom shapes and cone shapes.

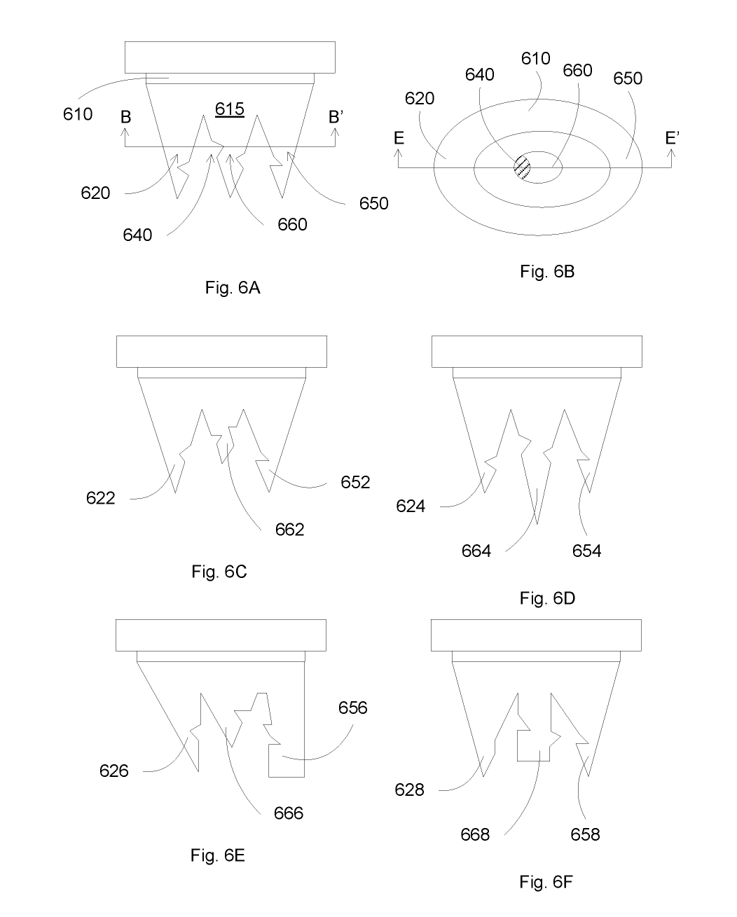

FIGS. 6A-6F illustrate other configurations for the contact bump according to some embodiments. In FIG. 6A, a cross section of a contact bump 615 is shown, which is disposed on a terminal pad 610. The cross section view of the contact bump 615 shows three tips 620, 650 and 660. Multiple recesses and protrusions 640 can be formed on the inner surfaces of the tips. FIG. 6B shows the cross section view of cut line BB′, with the tips 620 and 650 having a volcano shape and the tip 660 a cone shape in the middle of the volcano. FIG. 6A can be a cross section view of cut line DD′ of FIG. 6B. Other cross section views of cut line BB′ can be used, such as multiple pyramid-like cones (similar to that of FIG. 4B), one or two pyramid-like cones with one or two half-moon cones (similar to that of FIGS. 4C and 4D), multiple circular cones (similar to that of FIG. 4E), multiple partially surrounding walls (similar to that of FIG. 4F).

FIGS. 6C-6F show other cross section configurations of the contact bump, which can be viewed at a same direction as that of FIG. 6A. The different cross section configurations of the contact bump as shown in FIGS. 6C-6F can have the cross section view of cut line BB′ as shown in FIG. 6B, or can have different cross section views as discussed above.

In FIG. 6C, the middle tip 662 can be shorter than the surrounding tips 622 and 652. In FIG. 6D, the middle tip 664 can be longer than the surrounding tips 624 and 654. In FIG. 6E, the surrounding tips 626 and 656 can have vertical surfaces, e.g., planes parallel to the normal direction of the terminal pad or perpendicular to the plane of the terminal pad. The middle tip 666 can have slant surface for assist in filling the recesses and protrusions. In FIG. 6F, the middle tip 668 can have vertical surfaces. The surrounding tips 628 and 658 can have slant surface for assist in filling the recesses and protrusions.

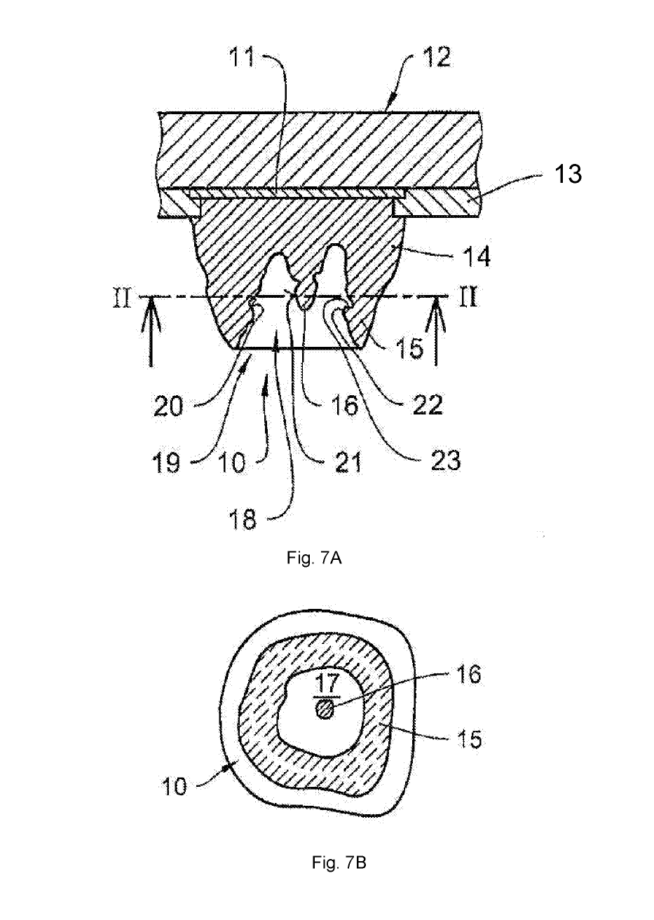

FIGS. 7A-7B illustrate a contact bump configuration according to some embodiments. FIG. 7A shows a cross section view of the contact configuration 10. FIG. 7B shows a cut view II-II. A contact bump configuration 10 can include a contact bump 14 formed on a terminal pad 11 of a semiconductor chip 12. Passivation layer 13 can be used to isolate the neighbor contact bumps. The contact bump 14 can have the shape of surrounding walls 15 and a middle cone 16 raised from the floor 17. The surrounding walls 15 can form a hollow chamber 18 with opening 19. The inner surfaces of the surrounding walls 15 can have multiple recesses and protrusions 20, 21, 22, and 23.

In some embodiments, the present invention discloses a contact bump with improve contact bonding with a contact pad. The improved contact bonding can include physical attachments between the surfaces of the contact bump and the surfaces of the contact pad. The physical attachments can include irregular interfaces with recesses and protrusions, which can enhance the separation resistance of the contact bump from the contact pad, especially for tensile and shear stresses.

In some embodiments, the contact bumps can include a non-smooth surface, e.g., a surface having irregularities, and another facing surface. The two surfaces can be tapered toward the terminal pad, e.g., the contact bump has a larger opening at the end of the bump (e.g., away from the terminal pad) as compared to a smaller opening nearer the terminal pad. The facing surface can form an angle with the normal direction of the terminal pad.

In some embodiments, the contact bump can include a wall surrounding a cone. The wall can have sharp ends for ease of penetration to the contact pad. The inner surfaces of the wall or the surfaces of the cone can be non-smooth, e.g., having irregularities such as recesses and protrusions.

In some embodiments, the contact bump can be formed by a deposition process, such as an electroless plating process. The contact bump can also be formed by a photolithography process, together with other processes such as deposition and etching. The contact bump can include palladium or palladium alloy materials.

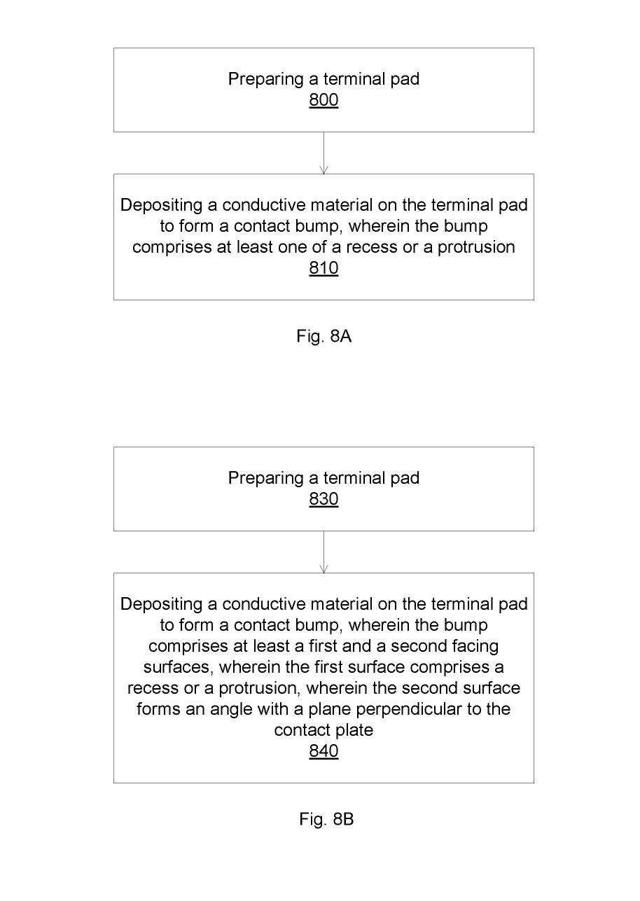

FIGS. 8A-8B illustrate flow charts for forming contact bumps according to some embodiments. In FIG. 8A, operation 800 prepares a terminal pad. The terminal pad can be formed on a substrate or on a semiconductor chip. Operation 810 deposits a conductive material on the terminal pad to form a contact bump. The contact bump can have an irregular surface with recesses and/or protrusions. The recesses and protrusions can be disposed on an inner surface of the contact bump, meaning a surface of the contact bump facing another surface of the contact bump. The irregular surface can include rough surfaces, e.g., the peaks and valleys of the rough surface can be considered as the recesses and protrusions, which can assist in securing the contact bonding of the bump connectors, one with contact bumps, to the corresponding contact pads. For example, during the contact bump formation process, such as an electroless deposition of the contact bump, the deposition can precipitate as spherical conglomerates, forming a micro roughness surface, which can be characterized as the recesses and protrusions of the contact bump surfaces. The conductive material can include palladium, such as palladium element or a palladium alloy.

In FIG. 8B, operation 830 prepares a terminal pad. The terminal pad can be formed on a substrate or on a semiconductor chip. Operation 840 deposits a conductive material on the terminal pad to form a contact bump. The contact bump can have two facing surfaces, with at least a surface having irregularities of recesses and/or protrusion, and a surface forming an angle with the normal direction of the terminal pad. The conductive material can include palladium, such as palladium element or a palladium alloy.

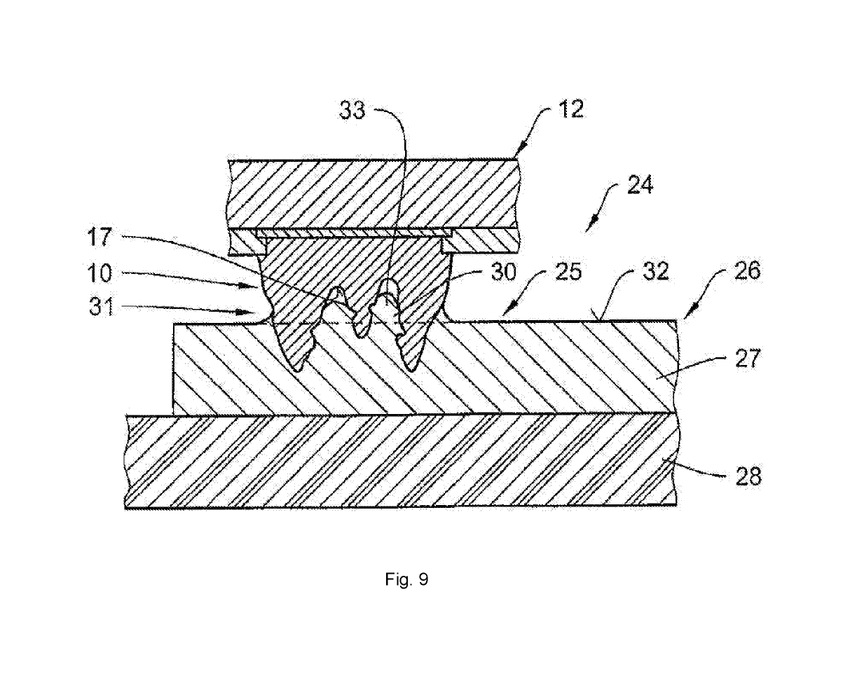

FIG. 9 illustrates a bonded configuration of a contact bump with a contact pad according to some embodiments. A bonded configuration 24 can include a top substrate 12 having a contact bump 10, and a bottom substrate 26 having a contact pad 27 on layer 28. The contact bump 10 can penetrate the contact pad 27 from the contact surface 32, with mating surfaces 30 between the contact bump 10 and the contact pad 27. The mating surfaces contain irregularities, such as recesses and protrusions, which can enhance the bonding between the contact bump and the contact pad. The irregularities can form physical attachments which can be effective against tensile force. For example, raised portions 31 and 33 from the contact pad 27 can enhance the contact surface between the bump 10 and the contact pad 27.

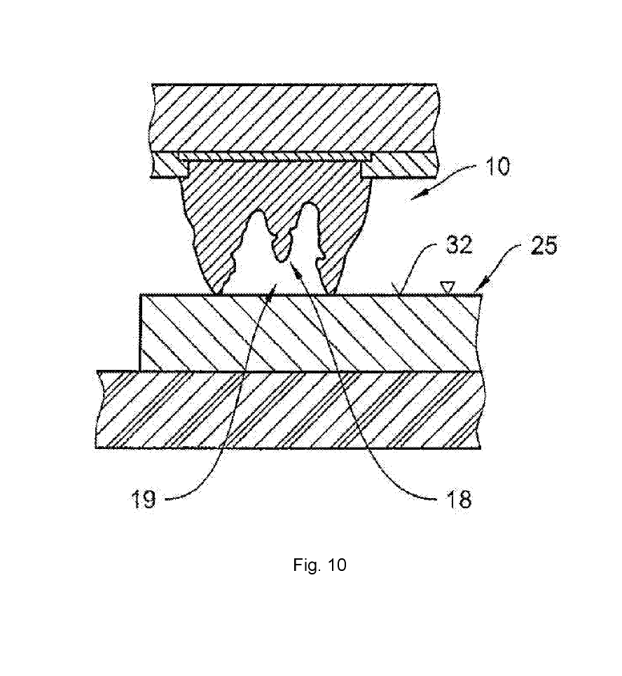

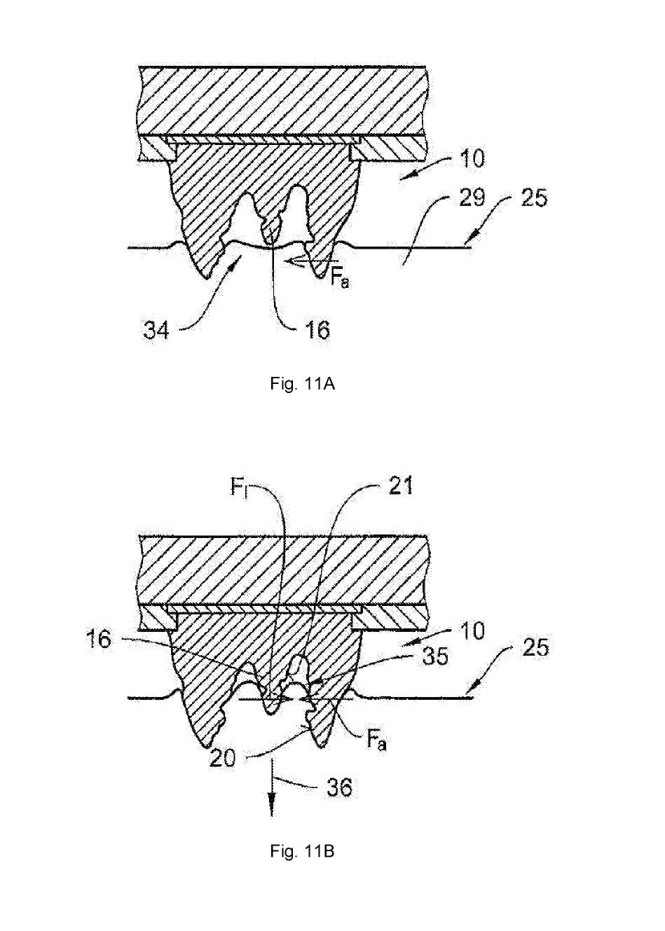

FIGS. 10-11A and 11B illustrate a process flow for forming the bonded configuration between a contact bump and a contact pad according to some embodiments. In FIG. 10, a contact bump 10 is brought into contact with a contact pad 25. The tips of the contact bump are shown to touch the surface 32 of the contact pad 25. The contact bump can form a chamber 19, surrounded by the walls of the contact bump. A middle cone 18 of the contact bump is disposed in the chamber 19.

In FIG. 11A, a force is applied to the contact bump to drive the contact bump into the contact pad. The walls of the contact bump can penetrate the contact pad surface, and can drive the material 34 of the contact pad inward (as shown by force Fa). As shown, the material 29 is outside the bump 10 and thus is not subjected to the force Fa. In FIG. 11B, the contact bump is further driven into the contact pad. The surrounding walls and the middle cone of the contact bump can penetrate the material of the contact pad, and can push the material inward for filling the recesses and irregularities of the inner surfaces of the contact bump. For example, forces Fa and Fi can push on the material of the contact pad to fill the hollow area 35 in the contact bump. Heating and agitation process can be added to assist in the flow of material to the surface irregularities. A vibration process, such as an ultrasonic vibration, can be used during the pressing of the contact bump into the contact pad. The vibration can be in a direction transverse to the pressing direction 36. Alternatively, or additionally, the vibration can be in the direction of the pressing direction 36.

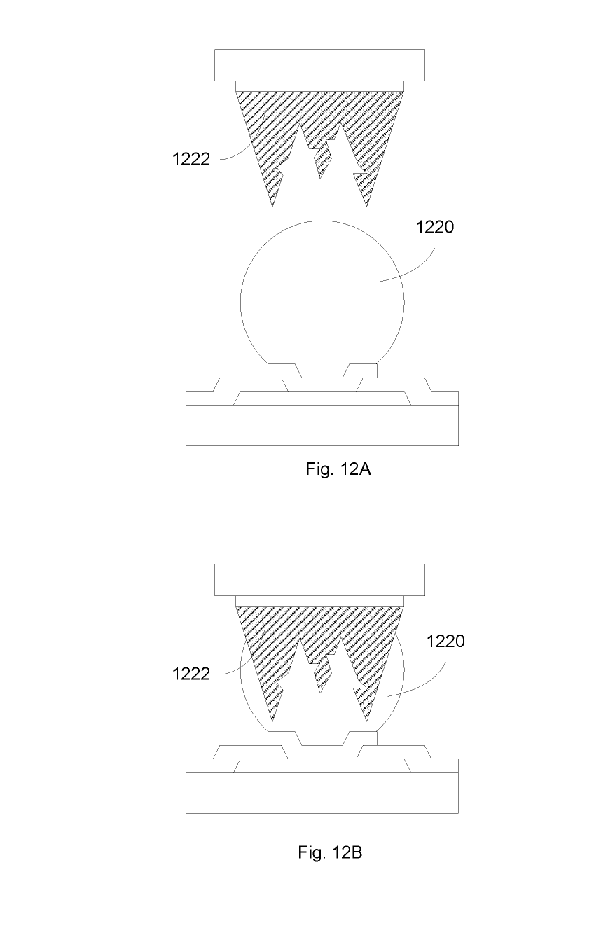

FIGS. 12A-12B illustrate another process flow for forming the bonded configuration between a top contact bump and a bottom contact bump according to some embodiments. A top contact bump 1222 having surface irregularities can be brought into contact with a bottom contact bump 1220. The top contact bump can penetrate the bottom contact bump, with the surface irregularities providing additional bonding strength for the bonded configuration.

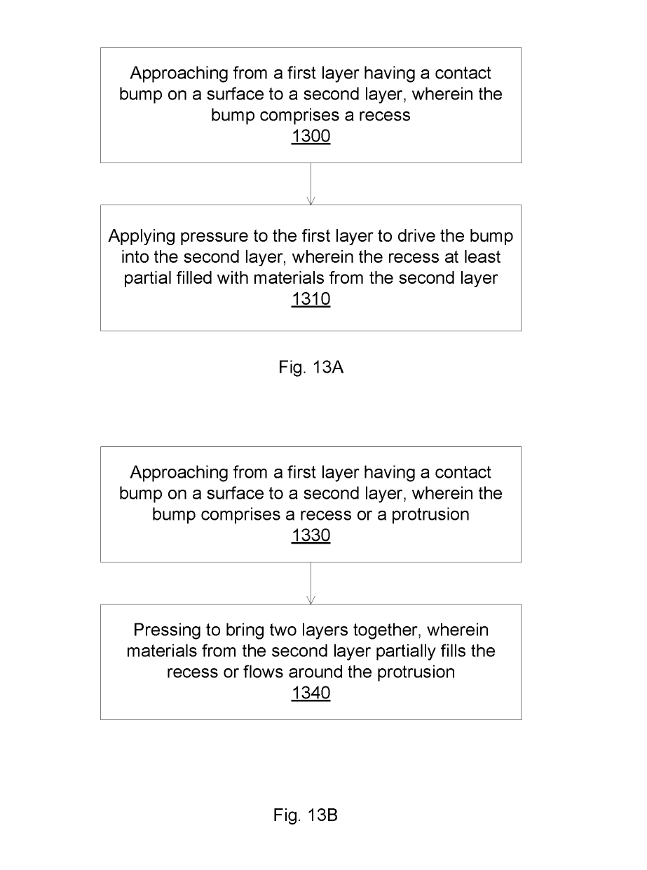

FIGS. 13A-13B illustrate flow charts for forming contact with contact bumps according to some embodiments. In FIG. 13A, operation 1300 approaches, by a first layer having a contact bump, to a second layer. The contact bump can have an irregular surface with recesses and/or protrusions. The recesses and protrusions can be disposed on an inner surface of the contact bump, meaning a surface of the contact bump facing another surface of the contact bump. The conductive material can include palladium, such as palladium element or a palladium alloy. The contact bump and/or the contact pad surfaces can be optionally coated with an adhesion layer. Operation 1310 applies pressure to the first layer to drive the contact bump into the second layer. The surface irregularities of the contact bump can be filled with the material from the second layer, which can strengthen the bond between the first and second layers.

In FIG. 13B, operation 1330 approaches, by a first layer having a contact bump, to a second layer. The contact bump can have an irregular surface with recesses and/or protrusions. The recesses and protrusions can be disposed on an inner surface of the contact bump, meaning a surface of the contact bump facing another surface of the contact bump. The conductive material can include palladium, such as palladium element or a palladium alloy. The contact bump and/or the contact pad surfaces can be optionally coated with an adhesion layer. Operation 1340 brings two layers together, wherein the configuration of the contact bump allows the material of the second layer to fill the surface irregularities.

In some embodiments, the bonded configurations with the contact bumps can be used for radio frequency identification (RFID) devices. The contact bump can be fabricated on the RFID chip, and the contact pads can be fabricated on a flexible element such as a substrate, antenna or device. The RFID chip can be bonded to the flexible element such as a substrate, antenna or device, forming a complete RFID device or RFID-Chip connected to the antenna creating a RFID device or product.

It is noted that the RFID device (or chip) may be flexible in some embodiments.

In some embodiments, the RFID device can be used on a card, e.g., a flexible surface. The enhanced bonding of the contact bonding between the RFID chip and the flexible element such as a substrate, antenna or device can significantly improve the reliability of the RFID card, for example, against bending during everyday usage.

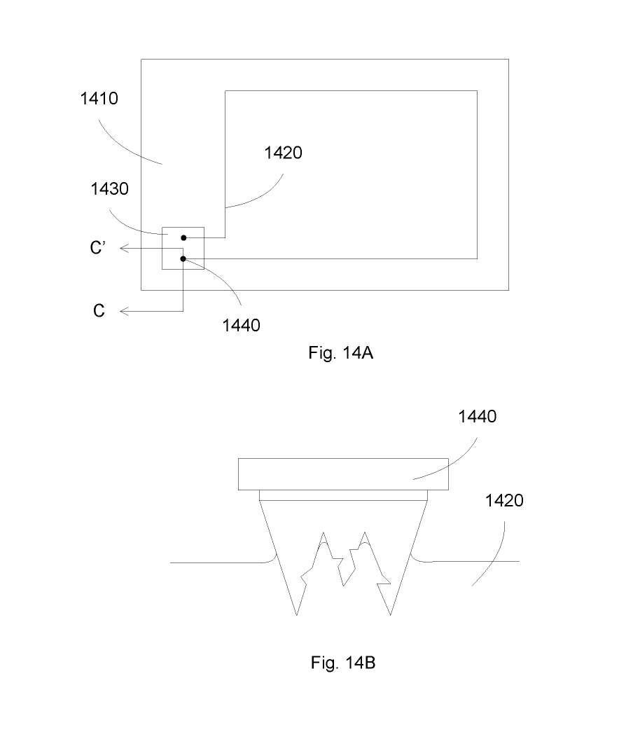

FIGS. 14A-14B illustrate a RFID card having a contact bump bonding according to some embodiments. A card 1410 can have a flexible element such as a substrate, antenna or device 1420 fabricated thereon. A chip 1430 having contact bumps 1440 can be bonded to the contact pads of the flexible element such as a substrate, antenna or device. The contact bumps can have surface irregularities, which can form intimate contact with the contact pads for better bonding strength.

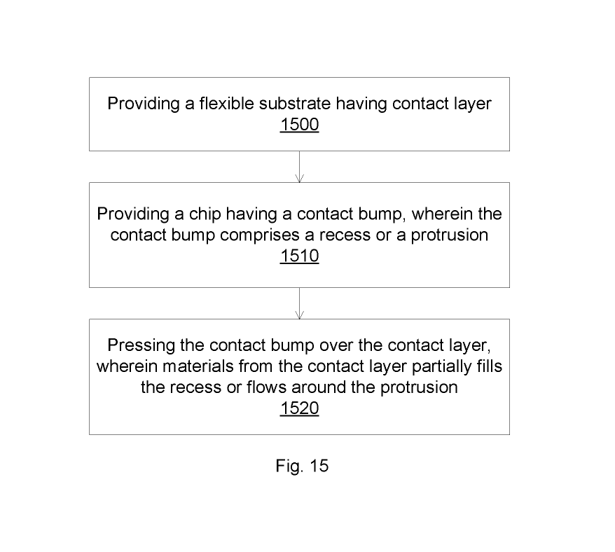

FIG. 15 illustrates a flow chart for forming a flexible element such as a substrate, antenna or device contact with contact bumps according to some embodiments. Operation 1500 provides a flexible substrate having contact layer or antenna having contact pads. The flexible element such as a substrate, antenna or device can be fabricated on a card, such as a smart card, a label, a ticket. Operation 1510 provides a chip, such as an RFID chip, having contact bumps. The contact bump can have an irregular surface with recesses and/or protrusions. The recesses and protrusions can be disposed on an inner surface of the contact bump, meaning a surface of the contact bump facing another surface of the contact bump. The conductive material can include palladium, such as palladium element or a palladium alloy. The contact bump and/or the contact pad surfaces can be optionally coated with an adhesion layer. Operation 1520 applies pressure to the first layer to drive the contact bump into the second layer. The surface irregularities of the contact bump can be filled with the material from the second layer, which can strengthen the bond between the chip and the flexible element such as a substrate, antenna or device. The contact bonding process can also include vibrating the components, in a direction transverse and/or along the direction of the pressing force. Thermal energy can also be provided.

In some embodiments, an adhesion layer can be provided on the contact bump before contacting the contact bump with the substrate.

In some embodiments, the present invention discloses a bump connection between a contact bump and contact pad on substrates or electronic components. The bump connection can include a conductive bump, which can electrically connect the contact pad and thus the substrates or electronic components. The contact bump or contact pad can be connected to a terminal of an electronic component, such as a radio frequency identification (RFID) chip. The substrate can include a contact bump or contact pad of another electronic component, or a terminal of a flexible element such as a substrate, antenna or device, which can be configured for coupling to the RFID chip.

The bump connection can include a contact pad, which has a lateral surface, which can be configure for bonding to a terminal of an electronic component, such as a device or a flexible element such as a substrate, antenna or device. The bump connection can include a contact bump. The contact bump can be coupled to the lateral surface. The contact bump can include a first surface and a second surface. The first surface can face the second surface. The first surface can include a recess or a protrusion. The second surface can form an angle with a direction perpendicular to the lateral surface.

In some embodiments, the first surface can surround the second surface. The second surface can surround the first surface. The contact bump can include at least a first and a second extended portions, the first extended portion can include the first surface, and the second extended portion can include the second surface. The second extended portion can form a hollow chamber which can surround the first portion. The first extended portion can surround the second extended portion. The second extended portion can surround the first extended portion. The first extended portion can be disposed next to the second portion. The second surface can include a recess or a protrusion. The first surface can form an angle with the perpendicular direction. The second surface can be operable to exert a force in a direction parallel to the lateral surface when the contact bump can be pushed against an object surface in a direction perpendicular to the lateral surface. The contact pad can be connected to a terminal of an electronic component. The bump connector can be configured to form a hollow chamber and a middle portion disposed in the hollow chamber. The hollow chamber and the middle portion can include the first and second surfaces. The first extended portion can be disposed in the hollow chamber. The material in the substrate can be configured to be mated with the recess or protrusion. The material in the substrate can be configured to be interlocked with the recess or protrusion. The second extended portion can surround the first extended portion. The first extended portion can be shorter than the second extended portion. The substrate can include a terminal end of a flexible element such as a substrate, antenna or device. The first extended portion can include a sharp tip. The second extended portion can include a sharp tip. The first and second extended portions can form a mushroom shape. The bump connection can be formed in an RFID device between a chip and a flexible element such as a substrate, antenna or device.

In some embodiments, the present invention discloses a bump connection. The bump connection can include a contact pad, a substrate, and a bump connector electrically connecting the contact pad and the substrate. The contact pad can include a lateral surface. The bump connector can be coupled to the lateral surface of the contact pad. The bump connector can include a first extended portion and a second extended portion. The first and second extended portions are at least partially embedded in the substrate. The second extended portion at least partially can surround the first extended portion. The first or the second extended portion can include a recess or a protrusion. The first and second extended portions are at least partially embedded in the substrate passing the recess or the protrusion. The first or the second extended portion facing the recess or the protrusion can form an angle with a direction perpendicular to the lateral surface, which can be operable to push the material of the substrate to mate with the recess or protrusion.

In some embodiments, the contact pad can be connected to a terminal of an electronic component. The bump connector can be configured to form a hollow chamber. The first extended portion can be disposed in the hollow chamber. The second extended portion can form a hollow chamber which can surround the first portion. The material in the substrate can be displaced to be mated with the recess or protrusion. The material in the substrate can be displaced to be interlocked with the recess or protrusion. The second extended portion completely can surround the first extended portion. The first extended portion can be shorter than the second extended portion. The substrate can include a terminal end of a flexible element such as a substrate, antenna or device. The first extended portion can include a sharp tip. The second extended portion can include a sharp tip. The first and second extended portions form a mushroom shape.

In some embodiments, the present invention discloses a method for forming a bump interconnect between a first contact pad and a substrate. The method can include pressing a bump connector on the substrate. The bump connector can be coupled to a lateral surface of the first contact pad. The bump connector can include a first extended portion having a first surface and a second extended portion having a second surface. The first surface can face the second surface. The first surface can include a recess or a protrusion. The second surface can form an angle with a direction perpendicular to the lateral surface. The pressing can be operable to displace the material in the substrate to interlock with the recess or protrusion of the bump connector. The method can include vibrating the bump connector during the pressing.

The material of the contact pad can flow in a lateral direction to fill the recess or a space above the protrusion. The vibration can be in a direction parallel to the lateral surface.

In some embodiments, the method can include forming an electronic component. The electronic component can include the first bump connector. The first bump connector can include the contact bump. The method can include forming a second component. The second component can include a second bump connector. The second bump connector can include a contact pad. The contact bump can be pressed on the contact pad of the second bump connector. The method can include forming an RFID chip. The RFID chip can include the first bump connector. It is also noted in other embodiments, the RFID chip can include the second bump connector. The method then can include forming the bump connector coupled to the lateral surface of a contact pad. The method can include forming a flexible element such as a substrate, antenna or device. The bump connector with contact bump can be pressed on a bump connector with contact pad of the flexible element such as a substrate, antenna or device.

In some embodiments, the present invention discloses contact bumps having rough surfaces, which can provide a physical locking with a corresponding substrate, e.g., a terminal pad, a contact pad or a bond pad of a separate component. For example, a first component, such as a bump connector of an RFID device, can have a contact bump with rough surfaces. The contact bump can be disposed on the contact pad of the RFID device. The RFID device can have one or more contact pads, such as two contact pads for externally bonding with two terminal pads of a flexible element such as a substrate, antenna or device.

When bonded with a second component, such as a contact pad of a flexible element such as a substrate, antenna or device, the contact bump can press on the contact pad, driving away the material in the terminal pad to form an improved electrical connection between the contact pads of the RFID device with the terminal pad of the flexible element such as a substrate, antenna or device. The improved electrical connection can include a physical locking feature, for example, due to the materials in the terminal pad flowing around the rough surface and securing the bond pad with the terminal pad to prevent connection loosening, for example, due to vibration.

The rough surface can be submicron or micron roughness, meaning a surface can be characterized as rough, e.g., having micro roughness, by having a height variation greater than 0.1, 0.2, 0.5, or 1 microns, or by having a minimum peak-to-valley height of 0.1, 0.2, 0.5, or 1 microns, and having a maximum peak-to-valley height of 10, 50, or 100 microns. For example, the peak-to-valley height of a rough surface can be between 0.1 to 100 microns, between 0.2 to 100 microns, or between 0.5 to 50 microns. The peak-to-valley height of the rough surface can be a minimum peak-to-valley height, a maximum peak-to-valley height, an average peak-to-valley height, or an average peak-to-valley height for a selected range (such as an average with a maximum and a minimum section removed, or an average with the outlier values, e.g., too small values or too large values out of range, removed).

In some embodiments, the surface can be characterized as rough by having a height variation greater than 0.5% or 1% of a dimension of the contact bump. For example, a contact bump can have a dimension of 50 microns, then the surface of the contact bump can be considered rough if the height variation of the contact bump is greater than 0.25 micron.

The rough surface can be formed during the formation of the contact bump, such as due to the formation of irregularities on the surface of the contact bump caused by a deposition process. For example, the contact bump can be formed by an electroless deposition of palladium, which can conglomerate or precipitate as spherical conglomerates.

In some embodiments, the contact bump can be disposed on a surface of bump connector. The contact pad can have a square shape, a polygon shape, such as an octagon, or a curve, such as circular or oval, shape. The contact bump can be formed in different configurations on the surface of the bump connector. For example, the contact bump can be formed on a periphery of the bump connector. The contact bump can also be formed on the interior of the bump connector. For example, the contact bump can be formed on a periphery and in the middle, e.g., inside the periphery. The contact bump can be formed randomly on the bump connector.

In addition, the contact bump can have one or more protuberances distributed on the surface. The protuberances can be discrete protuberances, e.g., forming multiple bumps that are separate from each other. The protuberances can be continuous protuberances, e.g., forming a wall of protrusions, with the top portion of the wall having similar or different height. The continuous protuberances can include a line of protrusions connected by a high ground, a series of more or less connected protrusions ranged in a line, or a group of protrusions located close to each other. The continuous protuberances can be similar to a mountain range. The contact bump can include discrete protuberances and continuous protuberances, e.g., there can be some protuberances standing separate from others, and some protuberances located close to each other with some overlapped at the bases of the protuberances.

The protuberances can have different sizes and shapes. For example, discrete protuberances can include large protuberances and small protuberances. In bump connector, large protuberances can be formed at a periphery of the connector, such as forming discrete protuberances at corners, forming discrete protuberances along a portion of a periphery, or forming a wall of protuberances along a portion of a periphery. Smaller protuberances can be formed in the middle. Continuous protuberances can include large protuberances located close to small protuberances, with overlapping bases.

In some embodiments, the contact bump can form a ring-like protuberance with hollow spaces in between. The ring-like protuberances can include continuous protuberances or discrete protuberances forming along a periphery of a bump connector. The ring-like protuberances can form a close ring configuration, e.g., the protuberances can surround the contact pad along the periphery or the protuberances can fill the periphery of the bump connector without gaps or with only small gaps in between. The ring-like protuberances can form an open ring configuration, e.g., the protuberances can be distributed along the periphery or the protuberances with large gaps in between.

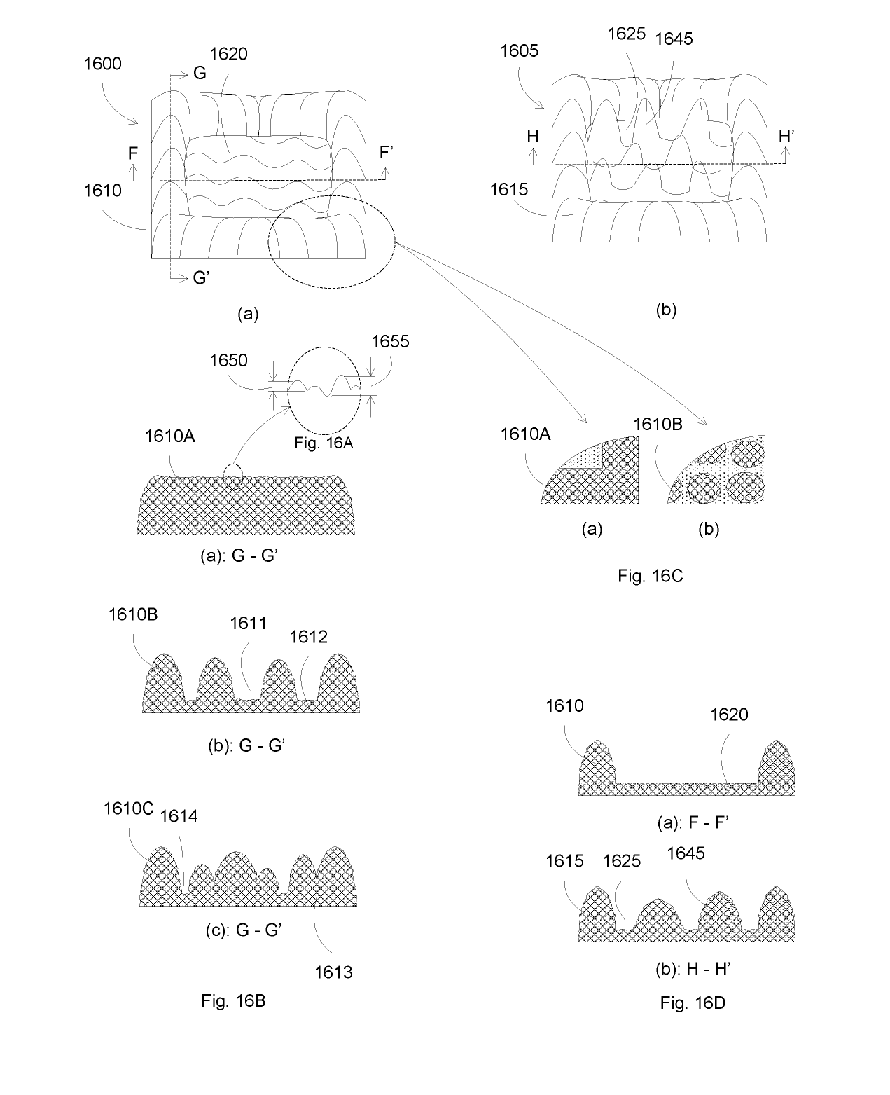

FIGS. 16A-16D illustrate contact bump configurations for a rectangular contact pad according to some embodiments. The contact pad shown is rectangular, but other shapes can also be used, such as square, polygon, or curve shapes. FIG. 16A shows 2 configurations of the contact bump. In FIG. 16A (a), the contact bump 1600 can include multiple protuberances 1610 disposed along a periphery of the bump connector. The surface of the protuberances 1610 can be rough, due to the deposition process when forming the contact bump. The area 1620 in the middle can be empty, e.g., there is no protuberance in the middle of the bump connector. The surface of the middle area 1620 can be rough, due to the deposition process when forming the contact bump. In FIG. 16A (b), the contact bump 1605 can include multiple protuberances 1615 disposed along a periphery of the bump connector. The area 1625 in the middle can include some additional protuberances 1645. The surfaces of the protuberances 1615 and 1645 can be rough, due to the deposition process when forming the contact bump.

FIG. 16B shows different configurations for the cross-section GG′ along a portion of the contact bump 1600. The contact bump can form a continuous wall 1610A, e.g., a solid wall with flat top (FIG. 16B (a)). The surface of the contact bump can be rough, e.g., having peak-to-valley height 1650 or 1655. The roughness can be micro-roughness, meaning the peak-to-valley height 1650 or 1655 can be between 0.1 and 100 microns.

In FIG. 16B (b), the contact bump can form discrete protuberances 1610B along a peripheral or a wall of the contact pad, including gaps 1611 between nearby protuberances. As shown, the discrete protuberances can have an overlapping base portion 1612. Alternatively, the discrete protuberances can be completely separated.

In FIG. 16B (c), the contact bump can form continuous protuberances 1610C along a peripheral or a wall of the contact pad, having small gaps 1614 between nearby protuberances. As shown, the discrete protuberances can have an overlapping base portion 1613. The continuous protuberances 1610C can also be considered as discrete protuberances with overlapping portions 1613.

FIG. 16C shows configurations for a portion of the top view of the contact bump. The protuberances 1610A can be continuous with no gap in between (FIG. 16C (a)). The protuberances 1610A can be discrete, forming separate peaks 1610B (FIG. 16C (b)).

FIG. 16D shows configurations for the cross-section FF′ along a portion of the contact bump 1600, and for the cross section HH′ along a portion of the contact bump 1605. The cross-section FF′ in FIG. 16D (a) shows the protuberances 1610 at a periphery of the bump connector with rough surfaces. There is no protuberance in the middle 1620 of the contact pad. The cross section HH′ in FIG. 16D (b) shows the protuberances 1615 at a periphery of the connector with rough surfaces. There is some smaller protuberance 1645 in the middle portion 1625 of the contact pad.

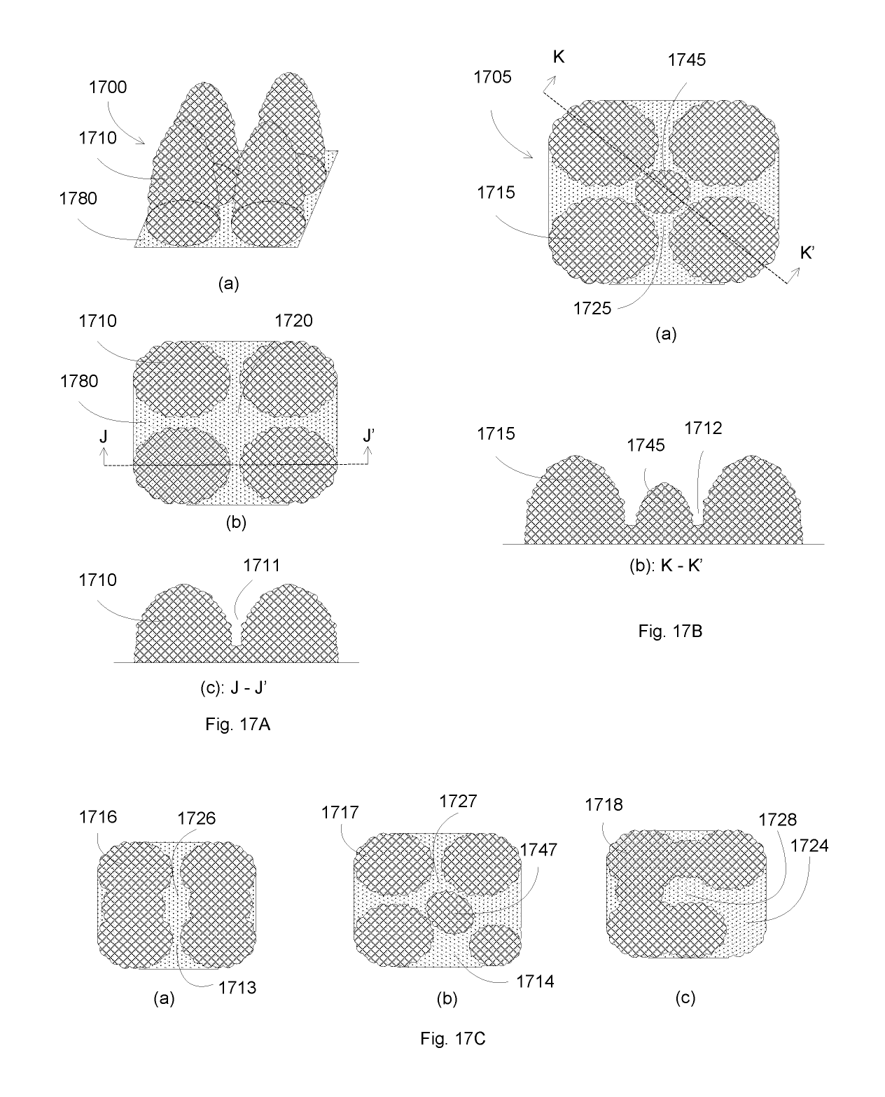

FIGS. 17A-17C illustrate other configurations for the contact bump according to some embodiments. The contact bump can include multiple protuberances having rough surfaces, such as micro-roughness surfaces. In FIG. 17A, a contact bump 1700 can include multiple discrete protuberances 1710 disposed on a square or rectangular bump connector 1680. The discrete protuberances can form a ring-like along a periphery of the bump connector, leaving hollow space 1720 in the middle. The ring-like configuration can be a close ring, e.g., the protuberances can be close to each other with a small gap 1711 in between.

In FIG. 17B, a contact bump 1705 can include multiple discrete protuberances 1715 disposed on a square or rectangular bump connector. The discrete protuberances can form a ring-like along a periphery of the connector. A protuberance 1745 can be formed in the space in the middle. There are some hollow spaces 1725 between the protuberances 1715 and 1745. The ring-like configuration can be a close ring, e.g., the protuberances can be close to each other with a small gap 1712 in between.

FIG. 17C shows other configurations for the contact bump. In FIG. 17C (a), the contact bump can have multiple protuberances 1716 forming along a periphery of a bump connector, leaving a middle hollow space 1726 and gap 1713. In FIG. 17C (b), the contact bump can have multiple protuberances 1717 forming along a periphery of a bump connector, together with a protuberance 1747 in a middle hollow space 1727. There can be large gaps 1714 in the periphery, between the protuberances 1717. In FIG. 17C (c), the contact bump can have multiple protuberances 1718 forming an open ring-like configuration along a periphery of a bump connector, leaving a middle hollow space 1728, and an opening 1724 in the ring-like configuration of protuberances 1718.

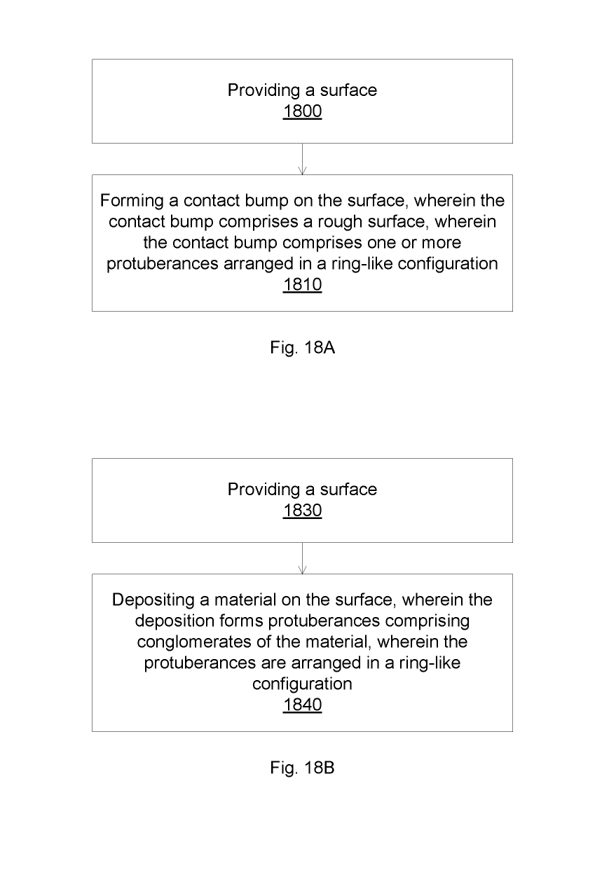

FIGS. 18A-18B illustrate flow charts for forming contact connection for a device according to some embodiments. In FIG. 18A, contact bump can be formed on a surface, such as the surface of a bump connector of a device. The contact bump can be used as a contact connection with another bump connector and contact pad of another device. Operation 1800 provides a surface, such as the surface of a bump connector of a device. For example, a device can be formed having input or output connections. Bump connectors can be formed, electrically coupled to the input or output connections.

Operation 1810 forms a contact bump on the surface. The contact bump can include a rough surface, such as a surface having micro-roughness, e.g., having a peak-to-valley height between 0.1 and 100 microns. The contact bump can include one or more protuberances arranged in a ring-like configuration. The ring-like configuration can be a close ring configuration, meaning the protuberances can be placed next to each other without any large gaps. For example, the protuberances can form a circle or can be placed along a complete periphery of a polygon surface. The ring-like configuration can be an open ring configuration, meaning there can be a large gap between the protuberances. For example, the protuberances can form a half moon circle or can be placed on only a portion of a periphery of a polygon surface.

In addition, the protuberances can form a solid wall, e.g., the protuberances can have a length similar to the length of a side or a periphery of the bump connector. The protuberances can be discrete or can be continuous, e.g., having overlapping bases.

The surface of the protuberances can be rough, for example, due to the deposition process during the formation of the contact bump.

In FIG. 18B, a deposition can be performed on a surface, such as the surface of a bump connector of a device. The deposition process can be configured to form one or more protuberances on the surface of the connector. The protuberances can form a contact bump, which can be used as a contact connection with another contact pad of another device. Operation 1830 provides a surface, such as the surface of a bump connector of a device. Operation 1840 deposits a material on the surface. The deposition can include electroless deposition (or other form of deposition such as electroplating or vapor deposition, e.g., physical or chemical vapor deposition). The deposition can form protuberances, which can be arranged in a ring-like configuration along a periphery of the bump connector, such as close ring or open ring configuration, together with optionally forming protuberances in the middle area of the ring-like configuration. The protuberances can have a rough surface, such as a micro roughness surface. The rough surface can be the result of the conglomeration of the deposited material. For example, during an electroless deposition of palladium, palladium can precipitate as spherical conglomerates, forming rough protuberances.

In some embodiments, the present invention discloses a contact connection between two substrates, such as between the bond pads or bump connectors of two separate device components. For example, a device can have one or more bond pads, which are configured to bond with corresponding bond pads of another device, with corresponding bond pads of a component, or with corresponding bond pads of a substrate.

The contact connection can include a bump connector with contact bump. The contact bump can be pressed on the other corresponding bump connector such as a bond pad or contact pad, to form an improved contact connection, for example, by having a physical locking feature due to the rough surface of the contact bump. The contact bump has been discussed above, and can include protuberances having micro roughness surfaces. Further, the structure of the contact bump, including the protuberances, can be configured to drive away material from the corresponding contact pad to facilitate strong surface interaction between the two bump connectors, with respectively contact bump and contact pads or bond pads.

In some embodiments, the hardness of the material of the contact bump can be higher than that of the corresponding bond pad or contact pad. For example, the contact bump can include palladium or palladium alloy, and the corresponding bond pad can include aluminum, gold, silver or copper. The difference in hardness values can allow the corresponding bond pad or contact pad to be deformed to the shape of the contact bump, and thus forming a contact connection with a high surface area and a physical locking feature due to the rough surface.

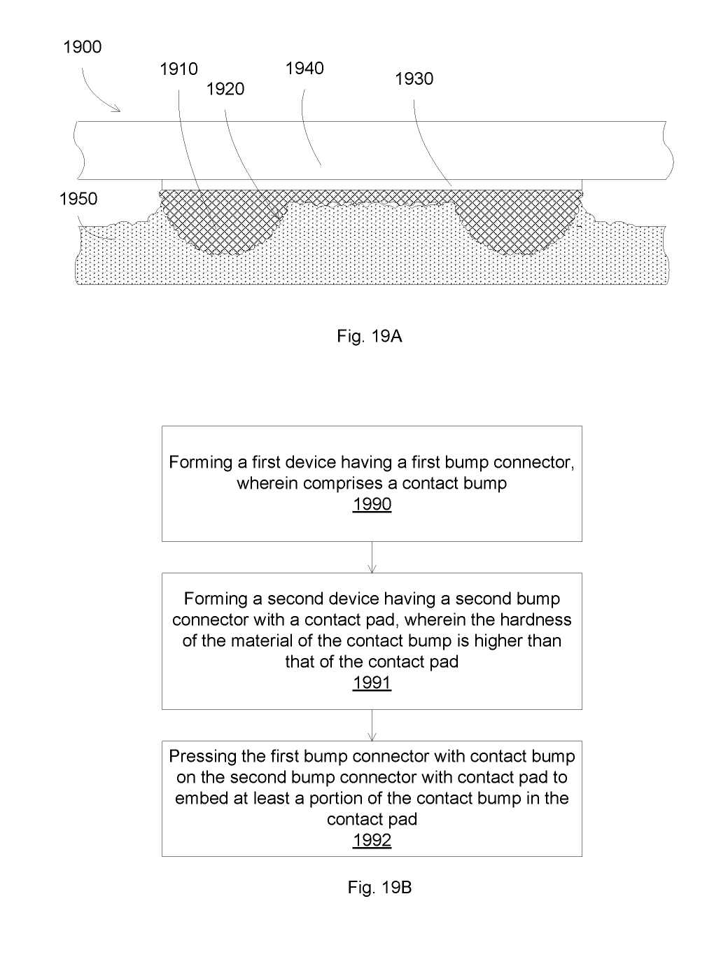

FIGS. 19A-19B illustrate a contact connection with a contact bump according to some embodiments. In FIG. 19A, a contact connection 1900 can include a first bump connector 1930, disposed on an external surface of a first device or component 1940, such as an RFID device. In the figure, a portion of the first device or component 1940 having the first bump connector 1930 is shown. The first device or component 1940 can extend beyond the picture frame.

A contact bump 1910 can be formed on the bump connector 1930. The contact bump 1910 can have a rough surface, for example, due to the deposition process, such as a precipitation as spherical conglomeration of the material during an electroless deposition. The contact bump can be pressed on a contact pad 1950 of a second device or component, such as the terminal pads or contact pads of a flexible element such as a substrate, antenna or device for the RFID device.

FIG. 19B shows a flow chart for the formation of a contact connection. Operation 1990 forms a first device having a first bump connector wherein comprises a contact bump. Operation 1991 then forms a second device having a second bump connector with a contact pad, wherein the hardiness of the material of the contact bump is higher than that of the contact pad. Operation 1992 than has the pressing of the first bump connector with contact bump on the second bump connector with contact pad to embed at least a portion of the contact bum in the contact pad. The first device can have one or more first bump connectors. Each of the first bump connectors can include a contact bump. The contact bump can have a rough surface. The first device can include an RFID device. The second device can have one or more second contact pads. The second device can include a flexible element such as a substrate, antenna or device for the RFID device. The rough surface of the contact bump can secure a good contact with the second contact pad, for example, by providing higher surface area, and a physical locking feature through the material in the second contact pad flowing out from the peaks and entering the valleys of the contact bump rough surface.

In some embodiments, the present invention discloses methods to form contact connection between two bump connectors, with one connector having a contact bump. A vibration or an oscillatory force can be included in driving the contact bump onto the opposite contact pad, for example, to assist in forming an improved contact connection.

In some embodiments, the contact bump can have a rough surface, e.g., protruding peaks and recessed valleys from the surface of the contact bump. The material from the opposite contact pad can flow around the rough surface, such as moving from the protruded peaks to the recessed valleys. The material flow can form a physical locking configuration, such as an intermesh between the contact bump and the opposite contact surface, which can assist in securing the contact connection between the two contact pads. The material of the contact bump can be harder, e.g., having a higher hardness value, than the material of the opposite contact pad, thus allowing the opposite contact pad to be deformed and flowed around the rough surface of the contact bump.

In some embodiments, the vibration or an oscillatory force, such as an ultrasonic pulsing, can assist in flowing the material from the opposite contact pad around the contact bump, together with forming an intermetallic connection between the materials of the contact bump and of the opposite contact pad. The ultrasonic pulsing can be applied to the contact bump, together with a force driving the contact bump into the opposite contact pad. The vibration of the contact bump can create a thermal energy, for example, at the frictional contact of the rough surface of the contact bump with the opposite contact pad. The thermal energy can heat up the contact surface for a short time, such as a few milliseconds. The thermal energy can soften the material of the opposite contact pad, helping the material to flow around the contact bump. Further, due to the heat, an intermetallic connection between the contact bump and the opposite contact pad can be created.

In a preferred embodiment, the present invention may provide then a contact connection, comprising at least a contact pad, wherein the contact pad may comprise of a pad surface and a contact bump wherein the contact bump may be coupled to a flexible electronic device, wherein the contact bump comprises a rough surface, and wherein the contact bump comprises one or more protuberances arranged along a periphery of the surface. The contact bump may then be connected to the contact pad. Additionally, the contact pad and contact bump form a contact connection between a flexible chip, element or device and the contact pad on a flexible substrate.

It may be noted that the flexible electronic device may be produced via thin-film technology, and/or by vacuum deposition. The device may also be a chip with a non-crystal structure. It may be also noted the rough surface may comprise a roughness having a peak-to-valley height greater than 0.01 microns and smaller than 5 microns and wherein the rough surface may be comprised of a deposited material during formation of the contact bump such as wherein the rough surface may be comprised of an electroless deposited material during a formation of the contact bump. This formation may be completed, such as wherein the contact bump may be connected to the contact pad by means of a press connection and wherein the press connection may be achieved by applying a supplemental vibrational force such as with a roller.

Additionally, a preferred method may be such that a user may form a connection comprising at least wherein the used provides a contact pad with pad surface and then may form a contact bump, wherein the contact bump is provided including a connection to a flexible electronic device. The user may provide depositing a material during the formation of the contact bump, wherein the material may form a rough surface wherein the rough surface comprises a roughness having a peak-to-valley height greater than 0.01 microns and smaller than 5 microns, wherein there may be one or more protuberances arranged along a periphery of the surface connecting the contact bump to the contact pad, and wherein the rough surface may be comprised of an electroless deposited material

It may be noted that the user may produce the flexible device via thin-film technology or via vacuum deposition and wherein the electronic device may be a chip with non-crystal structure.

It may be noted that the flexible substrate as mentioned, or element, or device, may be any type of element including complete devices or a component of a larger or other device or element, and as such may be for instance a flexible electronic element, such as an substrate, chip, device, semiconductor or display element including for instance, an electronic chip. In some embodiments then wherein the contact pad is on a flexible substrate, among any other permutation wherein the device or element is flexible, as mentioned. For instance the mentioned, device, substrate or other terms can be replaced by the above, or any other device.

It also may be noted that the user may form the connection between the contact bump and contact pad is provided by press connecting the contact bump and contact pad, wherein providing a supplemental vibrational force while press connecting and providing the pressing force with a roller.

The vibrational assisted bonding process can be highly cost effective, for example, the process can have lower operating cost than a standard thermo-compressing bonding with anisotropic conductive paste or non-conductive paste. Throughput can be enhanced, since the bonding time can be in order of seconds (or milliseconds). For example, the bonding heat, e.g., the thermal energy created to bond the contact bump with the opposite contact pad, can be generated in order of milliseconds, in contrast to a standard thermo-compressing bonding of between 6 and 9 seconds. The short heating time can prevent the contact connection from undergoing any distortion. Further, the high heat can form a chemical bonding, such as intermetallic connection between metal-based contact bumps and metal-based contact pads. Smooth bonding can be achieved using the vibrational assisted bonding process.

In addition, multiple bonding can be performed in parallel, e.g., a vibrational assembly can be used to process multiple contact connections, leading to a less number of bond heads. Thus, high throughput can be achieved, such as throughput of higher than 50,000 units per hour. This can provide a significant advantage over thermo-compressing bonding, since a high number, e.g., greater than 150, of thermal-compressing bond heads can be difficult to control, align and handle.

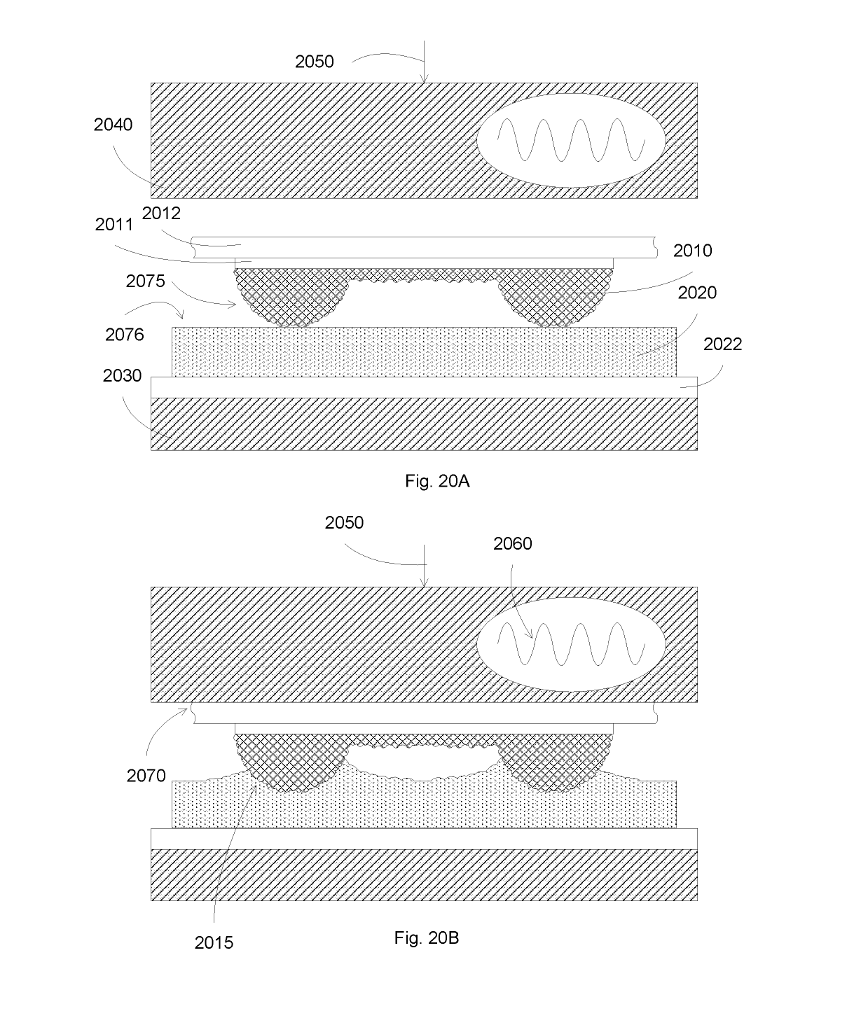

FIGS. 20A-20B illustrate a bonding process between two bump connectors according to some embodiments. A vibration or oscillatory force, such as an ultrasonic system, can be used to bond the two connectors.

A device, such as an RFID device, can have a bump connector 2011 for external connections. The connector 2011 can have a contact bump 2010 having a rough surface. A portion of the device 2012 is shown, showing one contact bump 2010 coupled to one connector 2011. In the figures, one bump connector 2011 is shown, but the device can have more than one. Further, the drawing is not to scale, for example, the contact bump 2010 is shown not proportional with the device.

The device portion 2012 can be placed on another device or component 2022, such as a flexible element such as a substrate, antenna or device. In some embodiments, the component 2022 can include a bond pad or contact pad 2020. In general, a bond pad or a contact pad is a component for forming an external connection, e.g., for forming an electrical connection with another component. The bond pad or contact pad can sometimes called a terminal pad or a connection pad. The contact pad 2011 and the bond pad 2020 can be aligned, e.g., the contact bump 2010 can be placed on the contact pad 2020.

The figures show the intrusion of one contact bump 2010 into one bond pad 2020, but the device 2012 can have multiple contact bumps connecting with multiple bond pads. The multiple bond pads can be from a same component 2022. For example, an RFID device can have two contact bumps, for coupling with two terminals of a flexible element such as a substrate, antenna or device. The multiple bond pads can be different components. For example, a device can be electrically connected to two different components. The device can have a first contact bump coupling with a bond pad of a first component, and a second contact bump coupling with a bond pad of a second component.

The figures also the component 2022 to be a separate element from the bond pad 2020. In some embodiments, the bond pad 2020 can include the same material as the component 2022.

In some embodiments, the component 2022 can function as a bond pad, e.g., the contact bump can be bonded directly to the component 2022, without the need for a bond pad. For example, the component 2022 can include a thin layer of material, and having a portion to act as a bond pad, e.g., so that the contact bump can penetrate and form an electrical connection. The portion act as the bond pad can be thicker than the rest of the component, for example, to accommodate the contact bump.

The bond pad 2020, e.g., a separate bond pad having a different material than that of the component 2022, a separate bond pad having the same material as that of the component 2022, or a portion of the component 2022 acting as a bond pad, can be made of a material that is softer than the material of the contact bump 2010. Thus, during the formation of the connection, e.g., the pressing of the contact bump 2010 into the bond pad 2020, the contact bump can be embedded in the bond pad without or with minimum distortion.

In some embodiments, an optional support 2030 can be used to support the component 2022. The support 2030 can include a substrate, which can support individual components, or can support multiple components. For example, multiple components can be disposed on a support. Different devices can be placed on corresponding components, and then bonded to the components through the contact bumps embedded in the component materials.

In some embodiments, supportless components, such as pure metal foils for flexible element such as a substrate, antenna or device materials, can be used. The devices can be placed directly on the supportless components, and bonded to the components through the connection between the contact bumps and the bond pad of the component, or between the contact bumps and the component.

A vibrational assembly 2040 can be provided. For example, an ultrasonic assembly 2060, which can include a piezo electric component, can be coupled to the assembly 2040 to generate an oscillatory action. The vibrational assembly 2040 can be pushed on the device 2012, e.g., a pressing force 2050 can be applied to the vibrational assembly 2040 to press the device 2012 on the component 2022. The vibrational assembly 2040 can drive the contact bump 2010 into the bond pad 2020 during the pressing force 2050 applied to the vibrational assembly 2040. The vibrational assembly 2040 can be moved in a direction perpendicular or substantially perpendicular to the contact pads.

The vibration force can improve the bonding between the contact pad 2011 and the bond pad 2020. For example, the vibration can help forming an intermesh between the rough surfaces of the contact bump with the bond pad 2020. The vibration can heat up the contact surface between the contact bump 2010 and the bond pad 2020, leading to a formation of intermetallic connection between the metallic contact bump 2020 and the metallic bond pad 2020.

Other configurations can also be used, such as a vibrational assembly can be coupled to the support 2030, instead of or in addition to the vibrational assembly coupled to the device 2012. Also, the vibrational assembly can be used to simultaneously drive multiple contact connections. Multiple components can be arranged for a same height bonding process, and can be bonded using one vibrational assembly. Multiple components can be placed next to each other, for a total size of about the size of the vibrational assembly.

In some embodiments, the vibration or oscillatory force can have a component in the direction of the pressing force, e.g., parallel to the pressing force. For example, the vibration or oscillatory force can be applied in a same direction as the pressing force. Alternatively, the vibration or oscillatory force can form an angle with the pressing force, and can be decomposed to include a parallel component and a perpendicular component. Thus, the pressing force can vary, for example, from a maximum value to a minimum value, together with an optional sideway vibration.

In some embodiments, the vibration or oscillatory force can be periodic, with a frequency of greater than about 10 kHz, preferred greater than 60 kHz. The amplitude of the vibration or oscillatory force can be greater than 1 micron. The amplitude of the vibration or oscillatory force can be smaller than 100 microns. In some embodiments, the amplitude can be greater than the spacing of the rough surface of the contact bump, such as greater than the average spacing of the peaks and valleys of the rough surface. The amplitude can be smaller than the thickness of the contact bump, such as less than 50 or 10% of the height of the contact bump.

In some embodiments, the pressing force can be large enough to drive the contact bump 2010 into the opposite contact pad 2020. For example, the pressing force can be greater than 0.1, 0.5 or 10N. The pressing force can be smaller than the fracture resistance of the contact connection assembly. In some embodiments, the time for bonding can be greater than a few milliseconds, such as greater than 20 or 100 ms.

In some embodiments, the vibrational assembly can be coupled to the contact pads with a high vibrational transmission from the vibrational assembly to the contact pads. A clean contact of the vibrational assembly to the device can be used, for example, to facilitate the vibrational transmission.

In some embodiments, a cleaning process can be applied to the vibrational assembly and/or the devices, for example, to increase the vibrational energy transmission. The cleaning process can remove contaminants, such as debris and adhered particles, from the contact surfaces 2070 of the vibrational assembly and/or the devices. For example, a cleaning device, such as a laser cleaning assembly, can be used to clean the surfaces of the vibrational assembly and/or the surfaces of the devices, such as by vaporizing the contaminants on the surfaces. The cleaning process can be performed before the vibrational assembly is in contact with the devices. In some embodiments, the cleaning time can be less than 1 minute, or less than 1 second.

In some embodiments, an optional adhesive layer can be used. The adhesive layer can be used to keep the components in position. e.g., keeping the contact bump 2010 aligned on the opposite contact pad 2020, before the final bonding process, e.g., before the contact bump can be pressed in the opposite contact pad. The adhesive layer can also be used for encapsulating the components, e.g., covering the contact connection between the contact bump and the contact pad.

The adhesive can be dispensed on the surfaces of the contact pads, such as on the surface 2075 of the contact bump and/or on the surface 2076 of the opposite contact pad 2020 or between or around contact pads. The adhesive can be brushed or sprayed. For example, multiple components, in a field of ca. 4 mm square, can be arranged next to each other, and an adhesive coating can be applied, for example, by spraying.

In some embodiments, the adhesive can be applied and then cured. For example, a layer of adhesive can be coated on the surfaces, and ultraviolet radiation can be used to cure the adhesive layer. The equipment for the adhesive dispensing and the adhesive curing can be located close to each other, and the components can be transported from the adhesive dispensing equipment to the adhesive curing equipment.

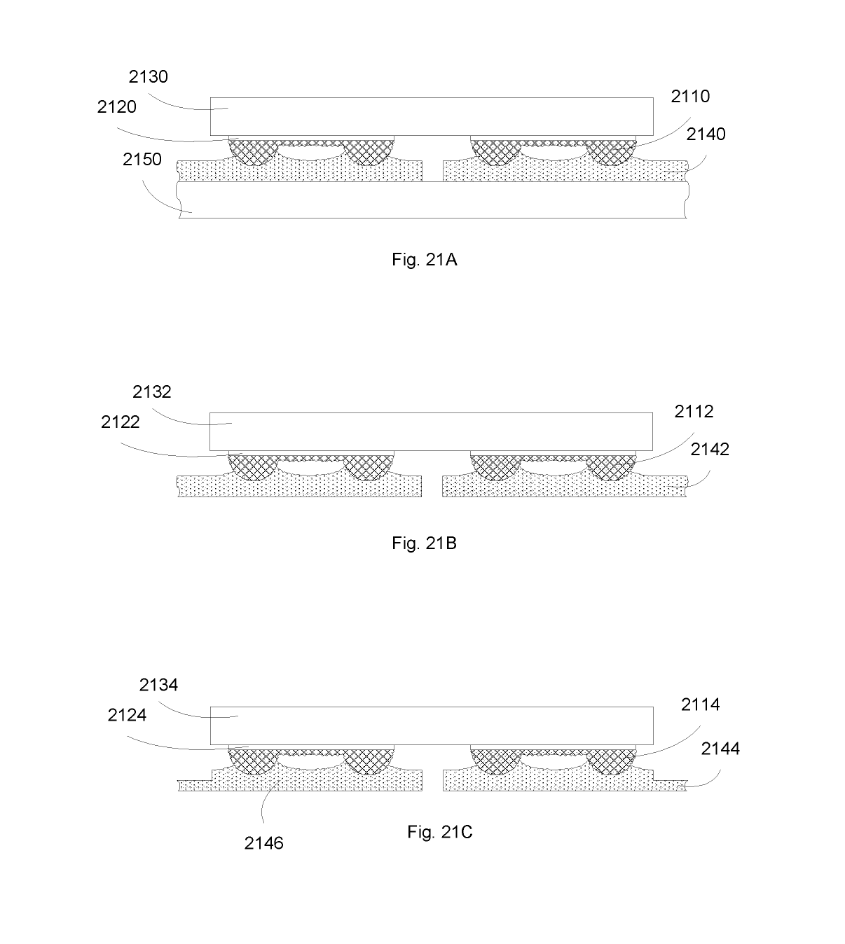

FIGS. 21A-21C illustrate bonding configurations according to some embodiments. In FIG. 21A, a device 2130, such as an RFID device, can have multiple bump connectors 2120 for external connections. The connectors 2120 can each have a contact bump 2110 having a rough surface. As shown, the device 2130 has two connectors 2120. In some embodiments, the device 2130 can have more than two contact pads, such as 4 contact pads.

The device 2130 can be placed on another device or component 2140, such as a flexible element such as a substrate, antenna or device. The component 2140 can be constructed so that the material of the component 2140 can be softer than the material of the contact bump. Thus, the component 2140 can act as a bond pad. For example, the contact bumps 2110 can be pressed into the component 2140, to form electrical connection between the device 2130 and the component 2140. The component 2140 can be placed on a support 2150, for example, to support the component 2140 against the pressing force acting on the device 2130. The pressing force can include a vibratory component, which can include a component in the direction perpendicular to a surface of the device 2130.

As shown, the support 2150 is used to support the component 2140. Alternatively, the support 2150 can be used to support the device 2130, with a pressing force acting on the component 2140.

In FIG. 21B, a device 2132, such as an RFID device, can have multiple bump connectors 2122 for external connections. The connectors 2122 can each have a contact bump 2112 having a rough surface. The device 2132 can be placed on another device or component 2142, such as a flexible element such as a substrate, antenna or device. The component 2142 can be constructed so that the material of the component 2142 can be softer than the material of the contact bump. Thus, the component 2142 can act as a bond pad. For example, the contact bumps 2112 can be pressed into the component 2142, to form electrical connection between the device 2132 and the component 2142. The component 2142 can be without a support, such as a foil substrate which can be used as the component.

In FIG. 21C, a device 2134, such as an RFID device, can have multiple bump connectors 2124 for external connections. The connectors 2124 can each have a contact bump 2114 having a rough surface. The device 2134 can be placed on another device or component 2144, such as a flexible element such as a substrate, antenna or device. The component 2144 can be constructed to have a portion 2146 having a thicker material at the area of contact with the contact bumps, to accommodate for the pressing of the contact bumps 2114 into the component 2144.

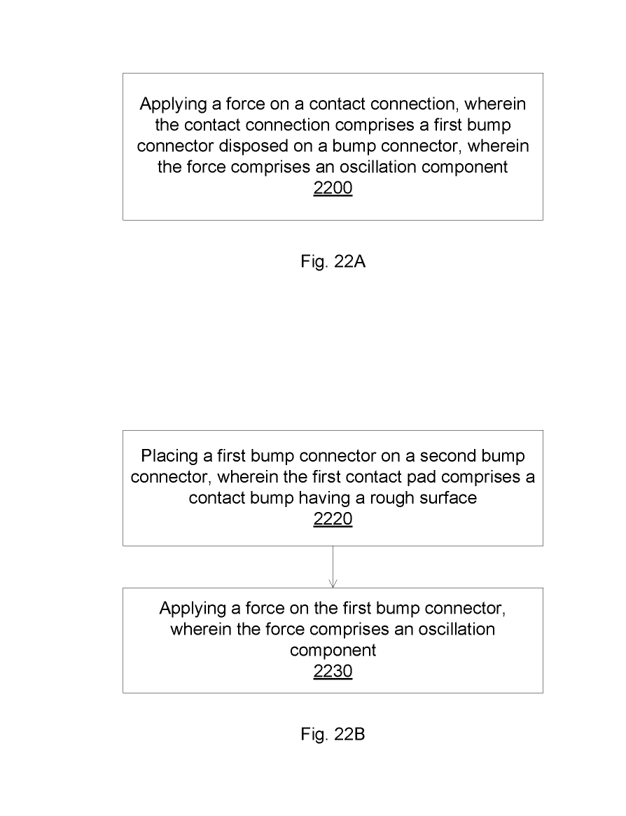

FIGS. 22A-22B illustrate flow charts for forming a contact connection according to some embodiments. A force that forms the contact connection can have an oscillatory component, such as an ultrasonic vibration, added to a linear force component pushing the contact pads together. In FIG. 22A, operation 2200 applies a force on a contact connection. The contact connection can include a first bump connector disposed on a second bump connector. The first connector can have a contact bump having a rough surface. The second connector can have a contact pad which can have a material that is softer than the material of the contact bump. The force can include an oscillation component. For example, the force can include a compression force, pressing the first bump connector, and contact bump, to the second connector with contact pad. The force can include an oscillatory component in the direction of the compression force, thus can vibrate the two-contact pad in the direction of the compression force.

The oscillatory component can include an ultrasonic vibration, which is added to the compression force in a general direction, such as perpendicular, parallel, or form an angle with the direction of the compression force.

In FIG. 22B, operation 2220 places a first bump connector on a second bump connector. The first bump connector can include a contact bump having a rough surface. The second contact bump connector can have a contact pad with material that is softer than the material of the contact bump.

Operation 2230 applies a force on the first bump connector. The force can include an oscillation component. For example, the force can include a pressing force, together with an ultrasonic vibration. The ultrasonic vibration can be applied to the pressing force in a general direction, such as perpendicular, parallel, or form an angle with the direction of the pressing force.

In some embodiments, a cleaning process, such as a laser cleaning process, can be used to clean the contact surface of the object that provides the pressing force for the first and second contact pads. A layer of adhesive can also be applied to the contact pad surfaces, such as to the top surface of the second contact pad, or to the surface of the contact bump of the first contact pad. An optional ultraviolet radiation curing can be used to cure the adhesive layer, before bonding the first and second contact pads.

In some embodiments, the present invention discloses a contact connection, for example, between two components, such as between two active devices, between an active device and a passive device, or between two passive devices. The contact connection can be performed between two bond pads, e.g., between a first bond pad of a first component, and a second bond pad of a second component.

One bump connector can have a contact bump, e.g., protuberances protruded from a surface of the bond pad. The other connector can have a bond pad can include a flat surface, having a material that is softer, e.g., having lower hardness, than the material of the contact bump.

In some embodiments, the bump connector can have a surface, on which a contact bump is formed. The contact bump can have a rough surface. The contact bump can include one or more protuberances arranged along a periphery of the surface. The protuberances may be highest on the periphery of a surface, or in a given pattern, such as the periphery ring of a circle may have higher protuberances than the interior circle. In other embodiments, the interior of a pattern or shape, such as the inner circle may have higher protuberances than a ring around the outside. The protuberance area may be any width, shape or pattern, and may have any cross-sectional height and difference between the high and low areas.

The rough surface can include a roughness having a peak-to-valley height greater than 0.1 microns and smaller than 100 microns, or greater than 1 microns and smaller than 20 microns. In other embodiments, the roughness may have any peak-to valley height difference.

A deposition process can be used to deposit a material on the surface of the bump connector. The deposition process can be under conditions so that the deposited material can form a contact bump, e.g., forming the one or more protuberances protruded from the surface of the bump connector. The deposition can include physical vapor deposition, chemical vapor deposition, electroplating, or electroless plating. For example, the rough surface can include a conglomeration of the material of the contact bump, a precipitation of a deposited material during a formation of the contact bump, or irregularities of a deposited material during a formation of the contact bump, which can be resulted by an electroless deposition process.

In some embodiments, the protuberances can form a continuous wall around the periphery of the surface of the bump connector. The protuberances can include distinct protuberances around the periphery. The distinct protuberances can have overlapping bases around the periphery. The protuberances can form an open ring or a close ring around the periphery. The contact bump can include a protuberance inside the periphery.

The other bump connector can be a contact pad or bond pad and can include a flat surface, having a material that is softer, e.g., having lower hardness, than the material of the contact bump. Thus, when bonded, for example, under a pressing force, the contact bump, e.g., the protuberances, can be at least partially embedded in the flat surface of the bond pad. In some embodiments, the contact bump can include structures configured to drive away materials in the second substrate to facilitate a strong surface interaction. For example, the structure can include protuberances having larger base portion than top portion, and protuberances having rough surfaces.

In some embodiments, the present invention discloses methods to form a contact connection, using a vibratory action to form an improved bond between a contact bump and a bond pad. The vibratory action can include an ultrasonic vibration, for example, formed by a piezo electric assembly, for vibrating the contact bump or the bond pad when the contact bump is pressed into the bond pad.

The contact bump can be pressed into the bond pad by a force that includes a pressing component and a vibratory component. The pressing component can be a substantially constant force, pressing the contact bump into the contact pad. The vibratory component can be an oscillatory force, such as an ultrasonic vibration, having a small vibration magnitude, e.g., smaller than a dimension of the contact bump or bond pad, such as less than 100 microns, or less than 25 microns.

For example, a vibrational assembly can be used for pressing the contact bump into the bond pad. The pressing component can include the pressing force acting on the vibrational assembly. The vibrationary assembly can provide the vibratory component, for example, the vibrational assembly can include an oscillatory component such as an ultrasonic vibration. Thus, by pressing the vibrational assembly on the contact bump on the bond pad, a combination force can be generated, which includes the pressing component and the vibratory component.

The vibrational assembly and/or the contact surface between the vibrational assembly and the components can be cleaned, for example, by a laser radiation, before pressing on the components.

In some embodiments, the method and device comprises wherein electroless, such as a process without the use of an electric current, chemically generated Pd bump forming precipitates (some in the form of amorphous protuberances, some in the form of crystals) selectively grown on flexible conductive material (212, 312, etc.).

In some embodiments, the present invention “broccoli” Pd bumps as mentioned the contact bumps, which allow superior contacting of flexible antenna materials, to the thin-film based electronic components (diodes, LEDs, chips, etc.), to allow improved contacting of flexible or solid contact partners as mentioned.

In some embodiments, a method to form a contact connection can include placing a contact bump facing a contact pad, and then applying a force on the contact bump or on the contact pad. Placing a contact bump facing a contact pad can include placing a contact bump on a contact pad, or placing a contact bump under a contact pad, or placing a contact pad under a contact bump, or placing a contact pad on a contact bump. The contact bump can include a rough surface. The material of the contact bump may have a higher hardness than the material of the contact pad. The force can include a substantially constant component and an oscillatory component.

In some embodiments, an adhesive layer can be applied on a surface of the contact pad or on a surface of the contact bump. The adhesive layer can undergo an ultraviolet radiation for curing or may be cured for instance by heat or exposure to ambient or the materials within the contact bump and contact pad, etc.

In some additional embodiments, the present invention may teach to Pd bumps on flexible chips. These may or may not be have a crystal structure. These may be formed or built by vacuum deposition processes and other common art practices of which for instance may be similar to thin film technology. In additional embodiments processes, such as printing processes allow electrical functionality besides silicon crystal devices and may ease in production of the devices. It is noted that some embodiment may include then wherein the structure is not a crystal structure but may be then a deposited structure or printed structure which may aid in flexibility and adherence.

In some additional embodiments, the construction of the flexible chips consists of a thin isolating substrate with added conductive and nonconductive structures to create micro electrical devices. Because the substrate and elements are flexible, then this may create then some embodiments wherein the chips/devices are thin and flexible. This may be made from such as palladium and may be formed for instance using a known electroless bumping process.

In some embodiments, the outer bump shape can be modified. In some embodiments contact bumps may be made such that connection pads of flexible electronic devices. The bumps may be made in any form by photo masking. This may also be possible on silicon crystals and any other substrates or materials.

When forming, the bumps may be forms such that the bumps may be in a specific area of a substrate such as on a ring around the exterior of a given surface or within the interior of a given shape.

In some embodiments, the present invention may provide wherein there may be an interconnection between two flexible components such as specific substrates. These may then also be flexible substrates and materials.

In some embodiments, the present invention bumps and substrates may be formed without ultrasonic methods of which may degrade the substrates and devices.

In some embodiments, the present invention may provide wherein the connection may be made wherein by winding and pressure force, where the rough surface provides a connection to the substrate terminals.

In some embodiments, the winding force can be part of the roll to roll process described, wherein when unwinding for instance a roll or strand of printed elements such as antennas with contact pads are sourced from a roll. Wherein then correspondingly, for instance chips with bumps, are rolled or dispended on the contact pads and wherein then the strand of elements together with the dispended electronic elements is upwound to form the outgoing roll. The upwinding exerts a winding force that contacts the pieces to each other and completes the marriage. In other words, this winding force leads to the mating of the rough bump surface into the flexible antenna material wherein the winding of the respective rollers mates and pressures the contact pad and contact bump together.

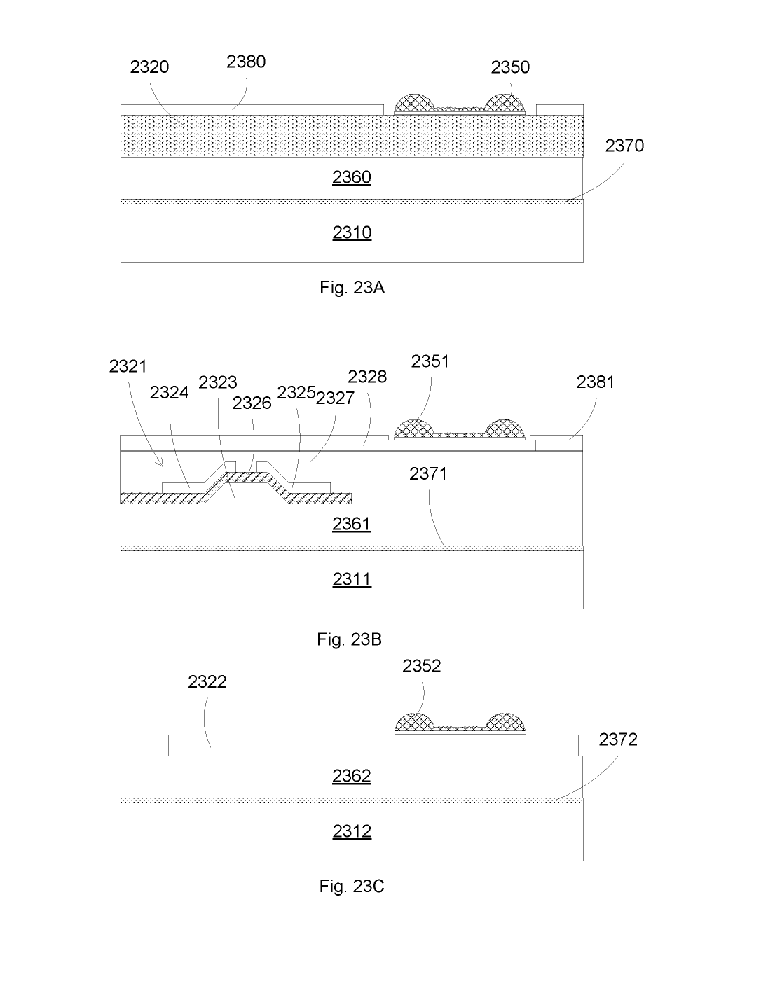

FIGS. 23A-23C illustrate contact bump configurations on a flexible substrate.

FIG. 23A shows a single layer of an electronic device 2320 of which can be formed on the substrate 2360 of which may be bonded to a layer 2310 of which may be any material and of which may include bond layer 2370 of any material, glue or attachment method. There then may be cover layer 2380 which may protect the device 2320 and of which may then include bump 2350 of which sits in a cut out of layer 2380.

FIG. 23B shows wherein a transistor 2321 can be formed on the substrate 2361. Gate 2323 can be formed on substrate 2361. An amorphous silicon layer 2326 can be deposited on the gate 2323, and then laser annealed to form a polycrystalline silicon layer. Source and drain 2324 and 2325 can be formed on the polycrystalline silicon layer, for example, by ion implantation. Via connection 2327 can be formed to connect the drain 2325. Bond pad 2328 can be connected to via 2327. The bump connector 2328 which then may be within a cover layer 2381 wherein then bump 2351 may extrude such that the bumps may be useable. Additionally, the above may then be adhered to a layer 2311 of which may include flexible materials to then provide the elements into a single flexible device.

FIG. 23C shows a similar bump on an RFID device on a flexible substrate such that a transistor 2322 can be formed on the substrate 2362 of which may be bonded to a layer 2312 of which may be any material and of which may include bond layer 2372 of any material, glue or attachment method. There then may be cover layer 2332 which may protect the transistor 2320 and of which may then include bump 2352 on the exterior of the layer.

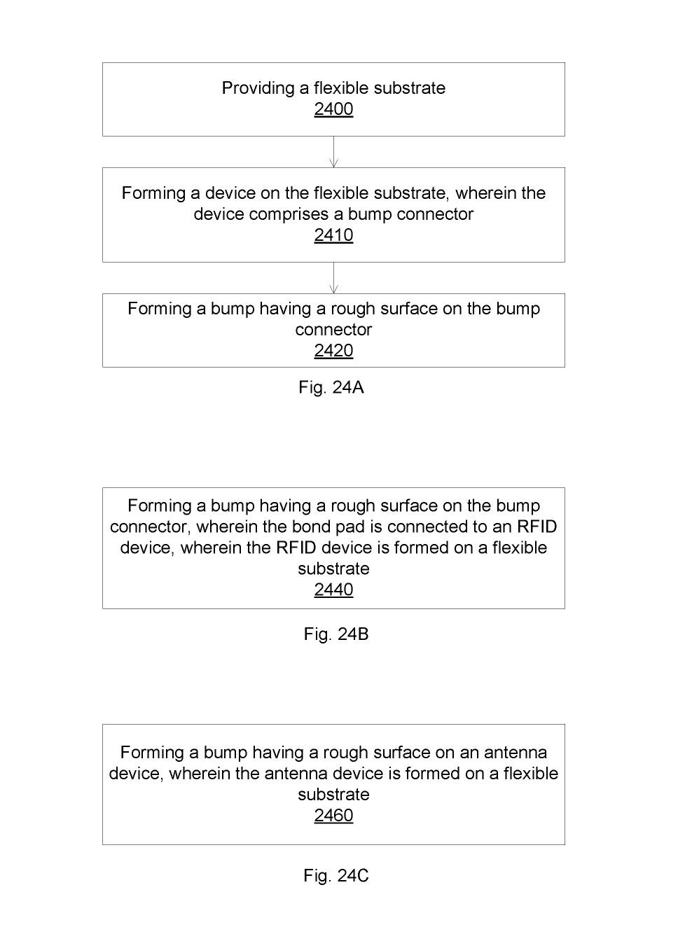

FIGS. 24A-24C illustrate flow charts for forming a bump for flexible substrates according to some embodiments.

FIG. 24A displays at least process 2400 wherein providing a flexible substrate, Process 2410 wherein forming a device on the flexible substrate, wherein the device comprises a bump connector and Process 2420 wherein forming a bump having a rough surface on the bump connector

FIG. 24B displays at least process 2440 wherein forming a bump having a rough surface on the bump connector, wherein the bump connector is connected to an RFID device, wherein the RFID device is formed on a flexible substrate.

FIG. 24C displays at least process 2460 wherein forming a bump having a rough surface on a flexible element such as a substrate, antenna or device, wherein the flexible element such as a substrate, antenna or device is formed on a flexible substrate.

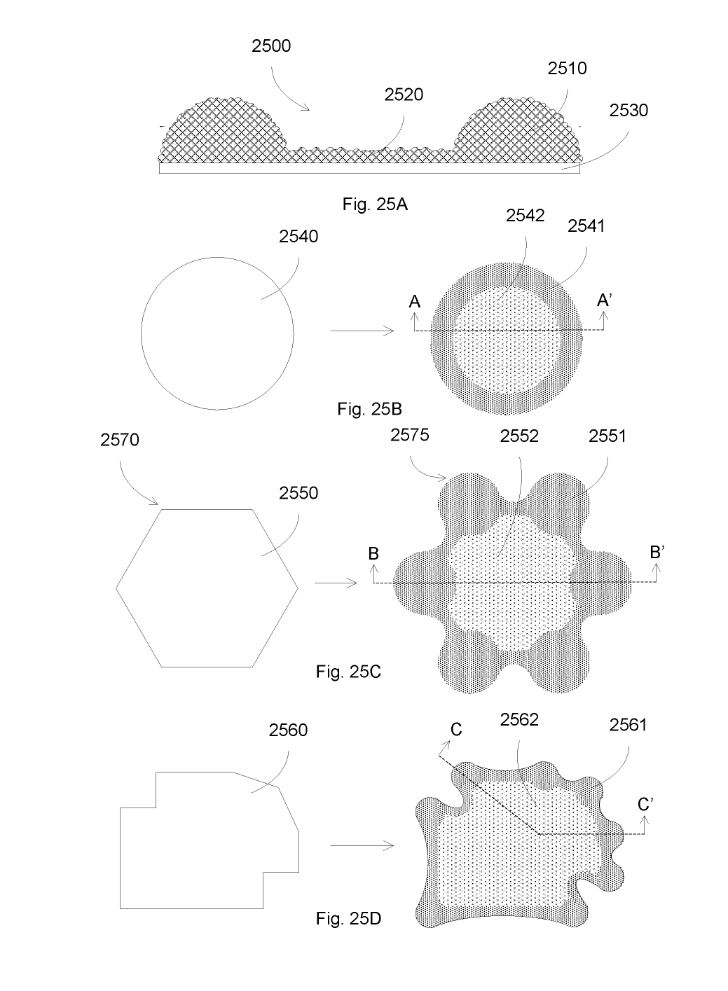

FIGS. 25A-25D illustrate contact bump configurations on a flexible substrate in different configurations and cross sections.

FIG. 25A shows a device 2500 wherein a substrate 2530 will form bumps wherein there may be corner or exterior bumps, to a specific area such as a cross section high bump profile 2510 and lower bump profile 2520.

FIG. 25B shows then the above wherein there may be a device 540 wherein then the cross section across A to A′ is seen to then include the higher bump or protrusion area 2541 and lower bumper or protrusion area 2542.

It is understood that the exterior being higher protrusion or bumper and interior lower protrusion is only for example and it can be seen any combination, pattern or area may be made. The patterns may be a byproduct of the shape, geometry or orientation of the object, such as due to surface area or other reasons during formation, or may be purposefully deposited or placed.

FIG. 25C shows then a device 2550 with corners 2560 wherein then bumps may exist and radiate or be made at the corners such as corner 2570 having bumps 2575 radiating and corner 2550 having bumper radiating 2551 wherein then a center lower bump area 2552 exists wherein when looked by cross section from B to B′. It is noted that the bumps may be such that the corners or areas of intersection, etc. may also be formulated to have the lower bumps.

It is noted in a preferred embodiment the corners seed the bumps for higher cross section area of bumps which may be beneficial to element use in that the corners or edges of may be necessitated for higher contact surface area, etc.

FIG. 25D shows an irregular shape wherein then a device 2560 forms bumper wherein a high bump area 2561 exists and a low bump section 2562 as seen from cross-section about C to C′

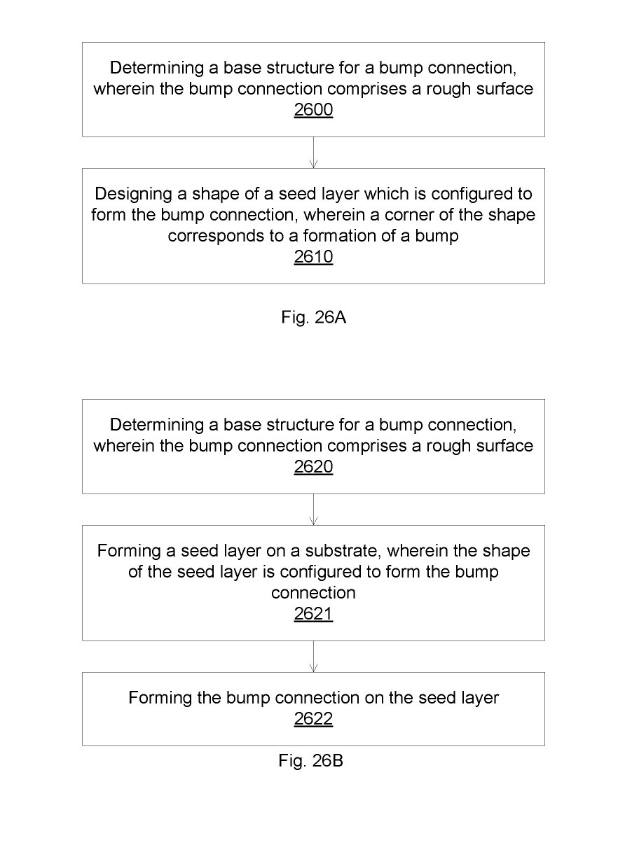

FIGS. 26A-26B illustrate flow charts for forming a bump for flexible substrates according to some embodiments.

FIG. 26A teaches to at least Process 2600 determining a base structure for a bump connection, wherein the bump connection comprises a rough surface and process 2610 designing a shape of a seed layer which is configured to form the bump connection, wherein a corner of the shape corresponds to a formation of a bump.

FIG. 26B teaches to at least Process 2620 Determining a base structure for a bump connection, wherein the bump connection comprises a rough surface, process 2621 forming a seed layer on a substrate, wherein the shape of the seed layer is configured to form the bump connection and process 2622 Forming the bump connection on the seed layer such as by using electroless for plating of Pd or other elements or substances.

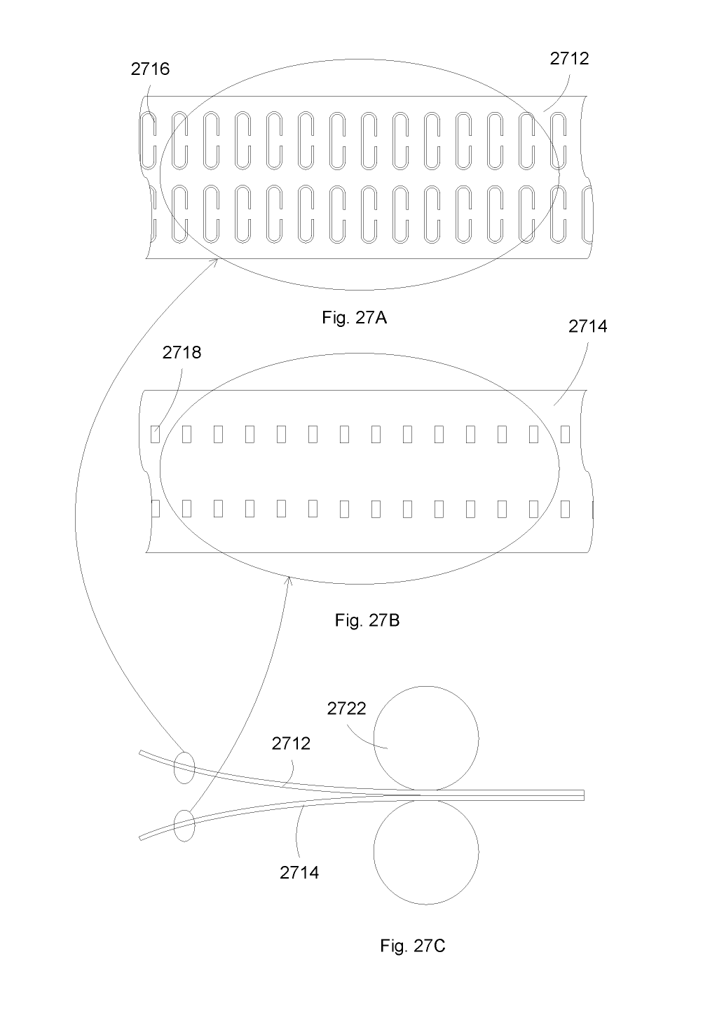

FIGS. 27A-27C illustrate forming contact bump configurations on a flexible substrate with rollers.

FIG. 27A shows a preprocessed or diced substrate roll 2712 of which may be flexible with embedded or otherwise formed device elements 2716 wherein a bump connection having a rough surface and contact bump or bumps.

FIG. 27B shows a preprocessed or diced substrate roll 2714 of which may be flexible with embedded or otherwise formed bump connector 2718 wherein the bump connector has bond pad comprises a material having lower hardness than the material forming the contact bump above.

FIG. 27C then shows using a roller or rollers 2722 wherein the elements 2712 and 2714 may then press the bump into the soft material of the bond pad of corresponding device, such as a roll to roll or reel to reel process to form devices with bump connections. This may allow for quick manufacturing and possible manufacturing on flexible devices.

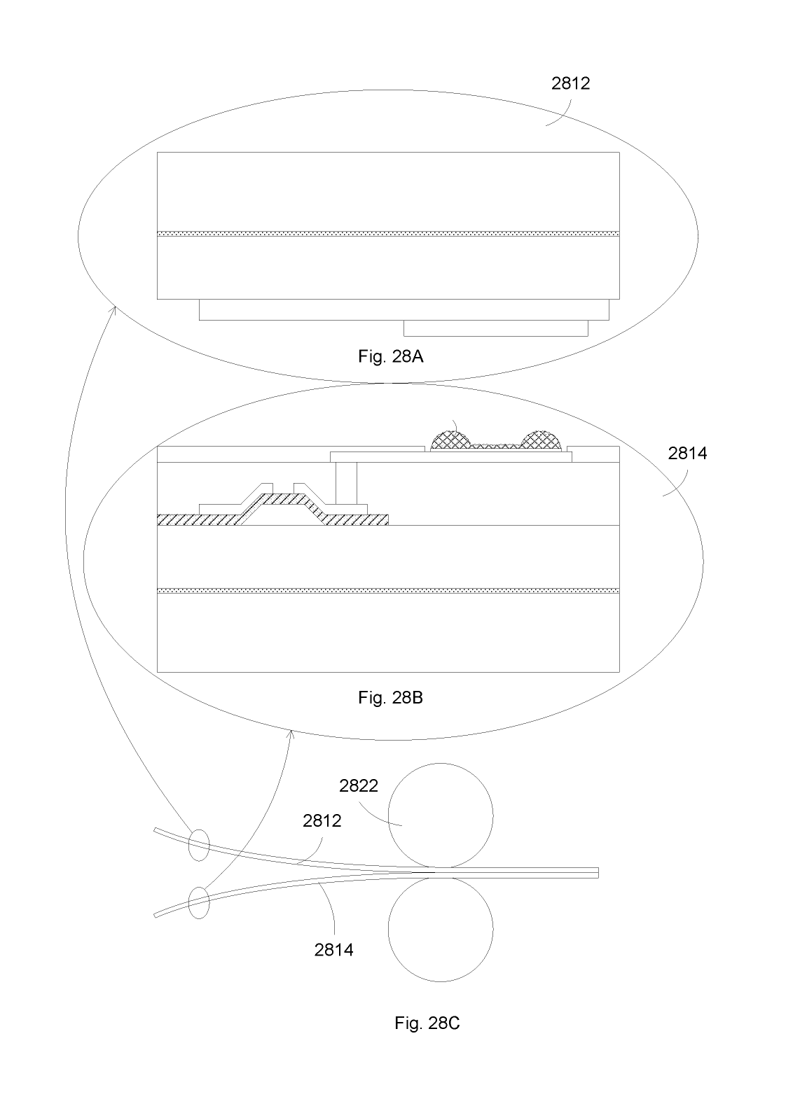

FIGS. 28A-28C illustrate forming contact bump configurations on a flexible substrate with rollers.

FIG. 28A then shows a roll as described in FIG. 23A wherein then substrate roll 2812 of which may be flexible with embedded or otherwise formed device elements wherein a bump connector comprises a bump connection having a rough surface with contact bumps.

FIG. 28B then shows a preprocessed or diced substrate roll 2814 of which may be flexible with embedded or otherwise formed bump pad wherein the bond pad comprises a material having lower hardness than the material forming the bump connection.

FIG. 28C then shows the two 2812 and 2814 rolled or pressed by roller 2822 such that the bumps contact and form a uniform device after rolling.

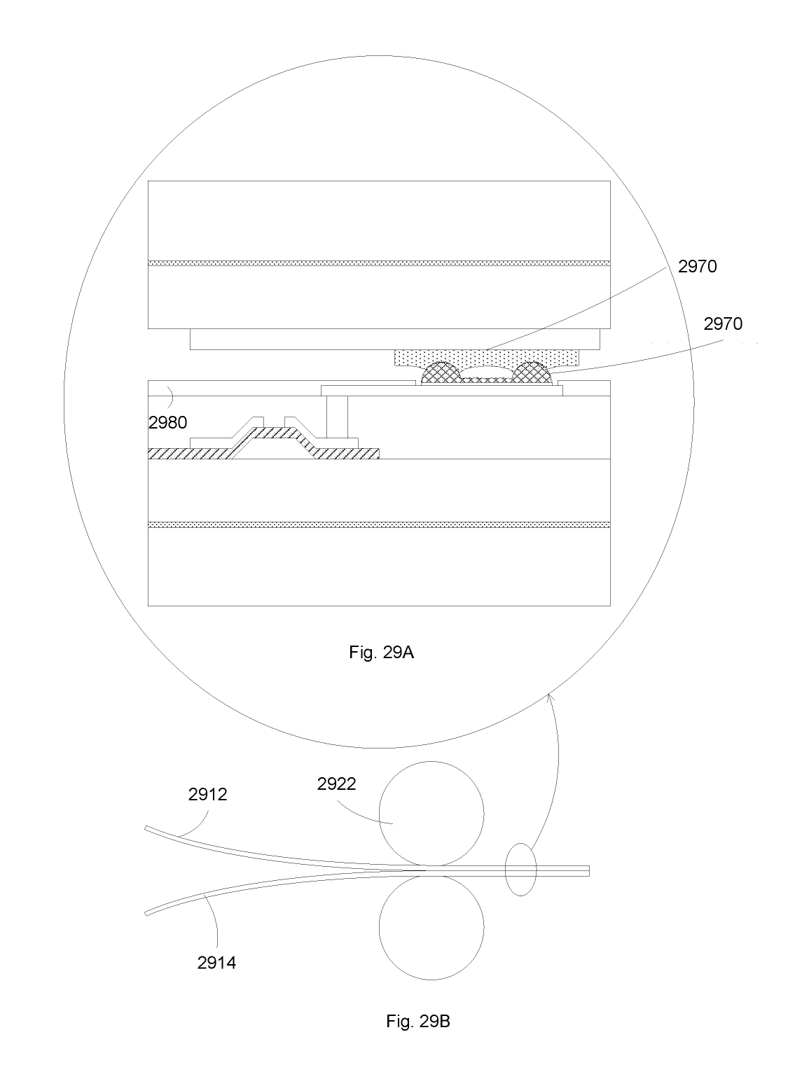

FIGS. 29A-29B illustrate forming contact bump configurations on a flexible substrate with rollers.

FIG. 29A shows then the two rolls 2912 and 2914 as previously described in FIGS. 23A, 23B, 28A and 28B wherein rolled as seen in 28C and within FIG. 29B, wherein the bumps press into the softer material such as 2970 and 2971. It is shown that the vertical or horizontal orientation of the soft pad can be vice versa and any orientation. FIG. 29B then provides the two rolls 2912 and 2914 press by roller 2922.

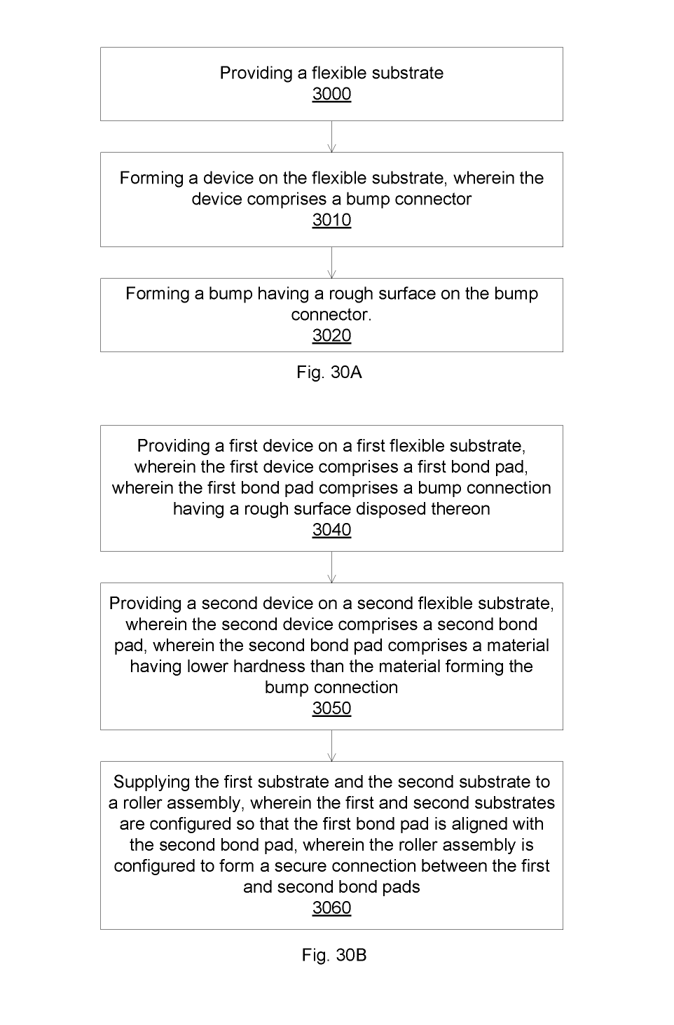

FIGS. 30A-30B illustrate flow charts for forming bumps and devices for flexible substrates and devices according to some embodiments.

FIG. 30A provides at least process 3000 wherein at least providing a flexible substrate, process 3010 wherein at least forming a device on the flexible substrate, wherein the device comprises a bump connector, and process 3020 wherein at least forming at least one contact bump such that the bump connector having a rough surface.

FIG. 30B provides at least process 3040 providing a first device on a first flexible substrate, wherein the first device comprises a bump connector, wherein the first connector comprises a bump connection having a rough surface disposed thereon, at least process 3050 wherein at least providing a second device on a second flexible substrate, wherein the second device comprises a second connector, wherein the second connector comprises a contact pad or bond pad comprises a material having lower hardness than the material forming the bump connection and process 3060 wherein at least supplying the first substrate and the second substrate to a roller assembly, wherein the first and second substrates are configured so that the first bond pad is aligned with the second bond pad, wherein the roller assembly is configured to form a secure connection between the first and second bond pads.

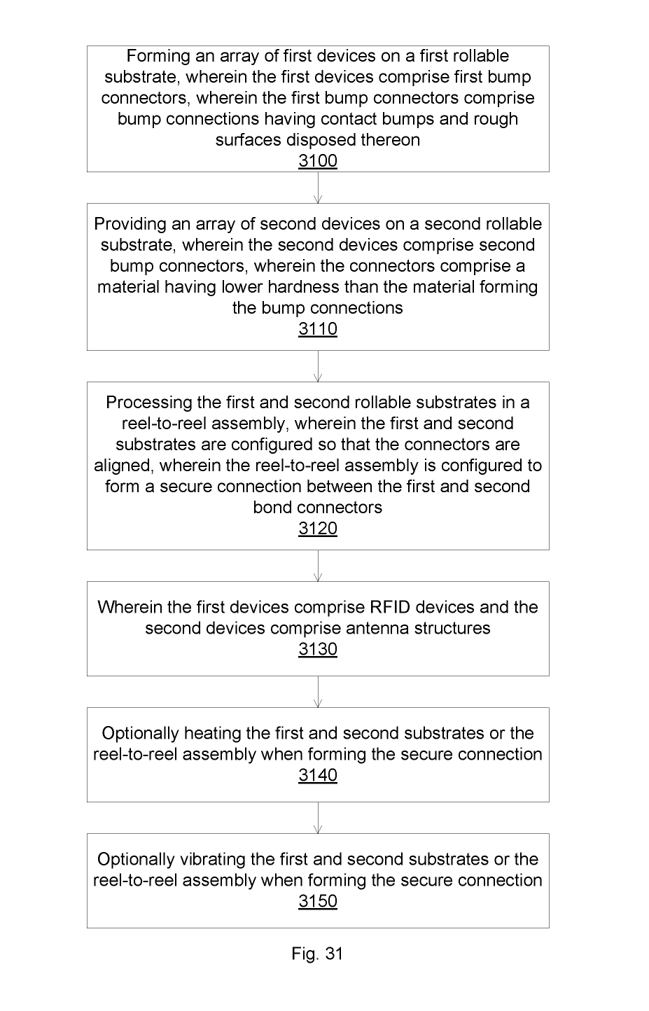

FIG. 31 illustrate flow charts for forming bumps and devices for flexible substrates and devices according to some embodiments.

FIG. 31 provides at least process 3100 forming an array of first devices on a first rollable substrate, wherein the first devices comprise first bump connectors, wherein the first bump connectors comprise bump connections having rough surfaces disposed thereon with contact bumps, at least process 3110 providing an array of second devices on a second rollable substrate, wherein the second devices comprise second bump connectors with contact pads or bond pads, wherein the second bond pads comprise a material having lower hardness than the material forming the contact bumps, at least process 3120 processing the first and second rollable substrates in a reel-to-reel assembly, wherein the first and second substrates are configured so that the first bond pads are aligned with the second bond pads, wherein the reel-to-reel assembly is configured to form a secure connection between the first and second bump connectors, at least process 3130 wherein the first devices comprise RFID devices and the second devices comprise flexible element such as a substrate, antenna or device structures, at least process 3140 optionally heating the first and second substrates or the reel-to-reel assembly when forming the secure connection and at least process 3150 Optionally vibrating the first and second substrates or the reel-to-reel assembly when forming the secure connection.

What is claimed is:

1. A contact connection, comprising:
a contact pad, wherein
the contact pad comprises a pad surface;
a contact bump, wherein
the contact bump is coupled to a flexible electronic element,
the contact bump comprises a rough surface,
the contact bump comprises one or more protuberances arranged along a periphery of the surface,
the contact bump is connected to the contact pad, forming a contact connection between the contact bump and the contact pad.

2. A contact connection as in claim 1:
wherein the flexible electronic element is at least one of a device, chip, semiconductor or display element.

3. A contact connection as in claim 1:
wherein the contact pad is on a flexible substrate.

4. A contact connection as in claim 1:
wherein the flexible electronic element is produced by vacuum deposition.

5. A contact connection as in claim 1:
wherein the flexible electronic element is produced via thin-film technology.

6. A contact connection as in claim 1:
wherein the flexible element is a chip with a non-crystal structure.

7. A contact connection as in claim 1:
wherein the rough surface comprises a roughness having a peak-to-valley height greater than 0.01 microns and smaller than 5 microns and wherein the rough surface comprises a precipitation of a deposited material during formation of the contact bump.

8. A contact connection as in claim 1:
wherein the rough surface is comprised of an electroless deposited material during a formation of the contact bump.

9. A contact connection as in claim 1:
wherein the contact connection between the contact bump and contact pad is a press connection via a pressing force.

10. A contact connection as in claim 9:
wherein the pressing force is from one or more rollers.

11. A contact connection as in claim 9:
wherein the press connection is achieved by a winding force.

12. A contact connection as in claim 9:
wherein the press connection is achieved by applying a supplemental vibrational force.

13. A method for forming a contact connection comprising:
providing a contact pad with pad surface on a flexible substrate,
providing a contact bump coupled to a flexible electronic element, which is at least one of a flexible chip, device, semiconductor or display element,
depositing a material during the formation of the contact bump wherein the material forms a rough surface, and
connecting the contact bump to the contact pad.

14. A method as in claim 13, additionally including:
forming the bumps by photo masking.

15. A method as in claim 13, additionally including:
producing the flexible electronic element via vacuum deposition such as thin-film technology.

16. A method as in claim 13, additionally including:
producing the flexible element as a chip with a non-crystal structure.

17. A method as in claim 13, additionally including:
forming protuberances arranged along a periphery of the surface of the contact bump.

18. A method as in claim 13, additionally including:
forming the connection between the contact bump and contact pad via a pressing force by press connecting the contact bump and contact pad via one or more rollers.

19. A method as in claim 13, additionally including:
supplying one or more rolls of a flexible material embedded with contact bumps and flexible elements, and one or more rolls of a flexible material, embedded with one or more contact pads;
feeding the rolls through at least a first and second roller, such that the contact bump and contact pad are aligned and pressed between the rollers to join into a single flexible device.

20. A method as in claim 13, additionally including:
heating the contact pad and contact bump.
